(19) United States
(12) Patent Application Publication
(10) Pub. No.: US 2024/0413019 A1
(43) Pub. Date: Dec. 12, 2024

(54) CFETS AND THE METHODS OF FORMING THE SAME

(71) Applicant: Taiwan Semiconductor Manufacturing Co., Ltd., Hsinchu (TW)

(72) Inventors: Ting-Yun Wu, Taipei City (TW); Jui-Chien Huang, Hsinchu (TW); Szuya Liao, Zhubei (TW)

(21) Appl. No.: 18/402,166

(22) Filed: Jan. 2, 2024

Related U.S. Application Data
(63) Continuation-in-part of application No. 18/503,892, filed on Nov. 7, 2023.
(60) Provisional application No. 63/607,771, filed on Dec. 8, 2023.
(60) Provisional application No. 63/507,205, filed on Jun. 9, 2023.

(51) Int. Cl. H01L 21/8238; H01L 29/06; H01L 29/417; H01L 29/423; H01L 29/66

(52) U.S. Cl. CPC H01L 21/823821; H01L 21/823814; H01L 21/823871; H01L 29/0673; H01L 29/41733; H01L 29/41791; H01L 29/42392; H01L 29/66439; H01L 29/66545; H01L 29/66795

(57) ABSTRACT

A method includes forming a first transistor in a first wafer, wherein the first transistor includes a first source/drain region, forming a first bond pad electrically coupling to the first source/drain region, forming an second transistor in a second wafer, wherein the second transistor includes a second source/drain region, forming a second bond pad electrically coupling to the second source/drain region, and bonding the second wafer to the first wafer, with the second bond pad being bonded to the first bond pad.

### PRIORITY CLAIM AND CROSS-REFERENCE

This application is a continuation-in-part application of application Ser. No. 18/503,892, filed on Nov. 7, 2023, and entitled “CFETs and the Methods of Forming the Same,” and this application claims the benefit of U.S. Patent Provisional Application No. 63/607,771, filed on Dec. 8, 2023, and entitled “CFETs and the Methods of Forming the Same,” and U.S. Patent Provisional Application No. 63/507,205, filed on Jun. 9, 2023, and entitled “CFET Scheme Options,” which applications are hereby incorporated herein by reference.

### BACKGROUND

Complementary Field-Effect Transistors (CFETs) are being developed to meet the increasing demanding requirement for increasing the density of transistors in integrated circuits. CFETs are thus developed. A CFET includes a lower transistor and an upper transistor overlapping the lower transistor. The lower transistors and upper transistors of multiple CFETs may be interconnected through local interconnect structures to form functional circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1N, 2A-2G, 3A-3J, 4A-4L, 5A-5I, and 6A-6I illustrate the views of the formation of CFETs through sequential formation processes in accordance with some embodiments.

FIGS. 7A-7J, 8A-8G, 9A-9J, 10A-10E, 11A-11E, and 12A-12C illustrate the views of the formation of CFETs through parallel formation processes in accordance with some embodiments.

FIG. 13 illustrates a process flow for forming CFETs through a sequential formation process in accordance with some embodiments.

FIG. 14 illustrates a process flow for forming CFETs through a parallel formation process in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) including upper transistors and lower transistors are provided. The local interconnects for interconnecting the upper Field-Effect Transistors (FETs, alternatively referred to as transistors hereinafter) and the lower transistors and the methods of forming the local interconnects are provided. In accordance with some embodiments, the CFETs are formed through sequential or parallel processes. This provides the flexibility in the materials and the structures of the upper transistors and the lower transistors. For example, the upper transistors and the lower transistors may be formed on semiconductor materials having different surface orientations. Also, the upper transistors and the lower transistors may have different structures such as different number of nanosheets. The upper transistors and the lower transistors may also be selected from Gate-All-Around (GAA) transistors and Fin Field-Effect Transistors (FinFETs).

Although the example embodiments provide specific combinations of GAA transistors and FinFETs as the upper transistors and the lower transistors, other combinations different from the example embodiments are also in the scope of the present disclosure. The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

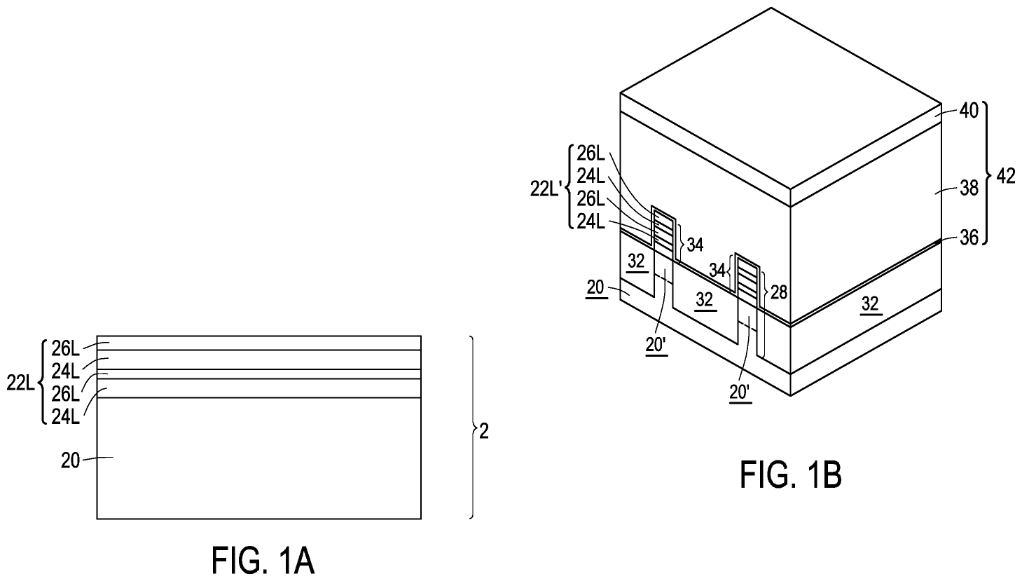

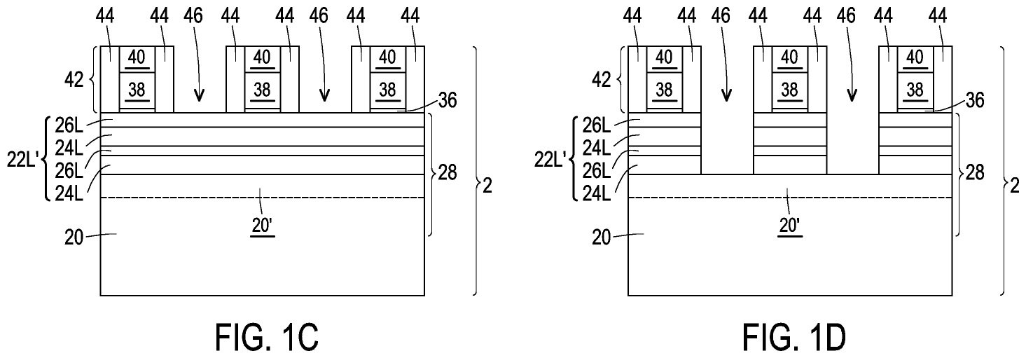

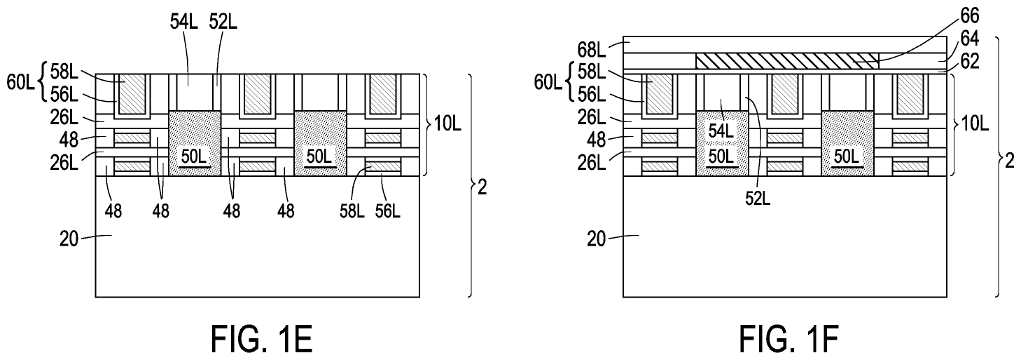

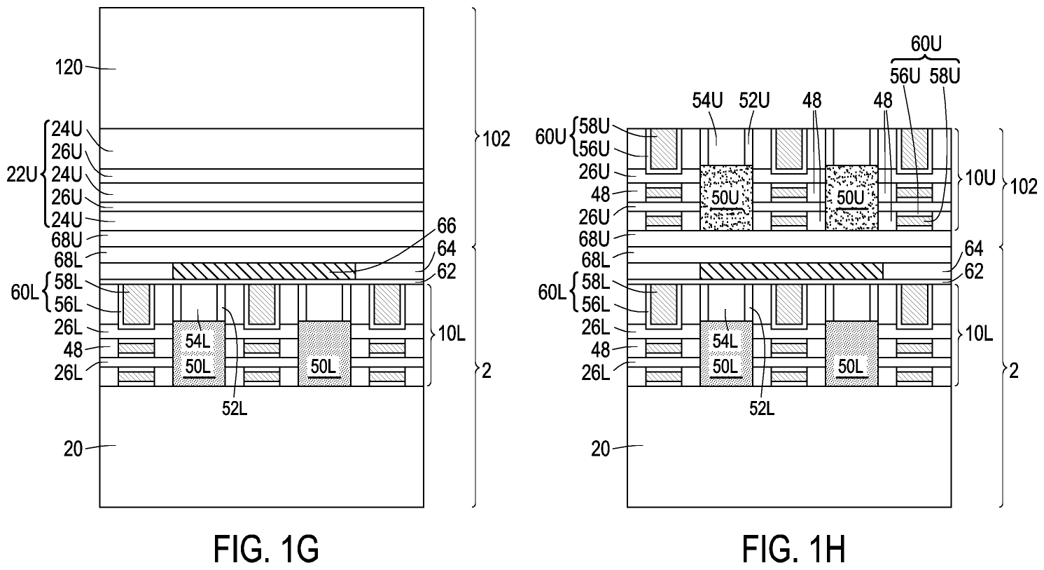

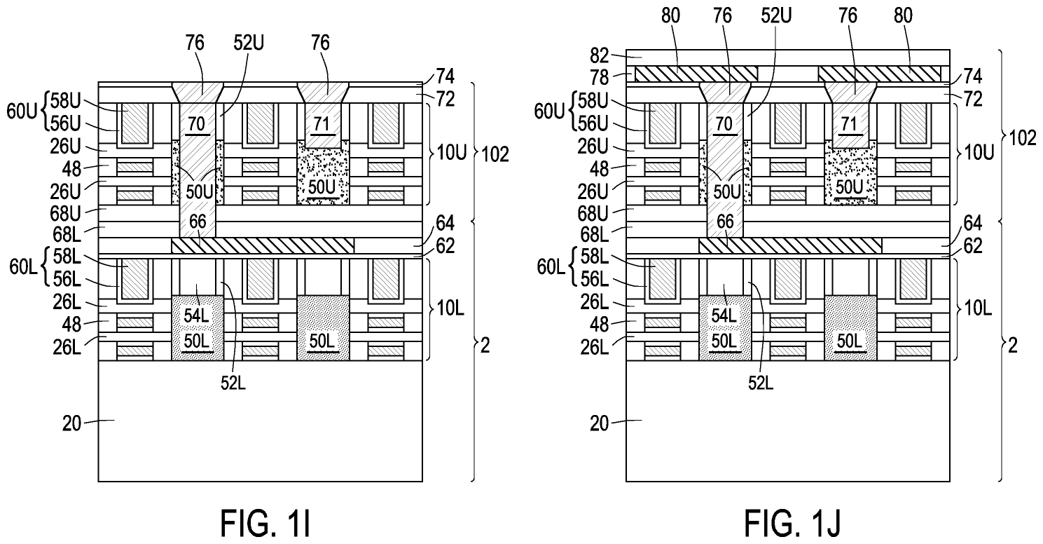

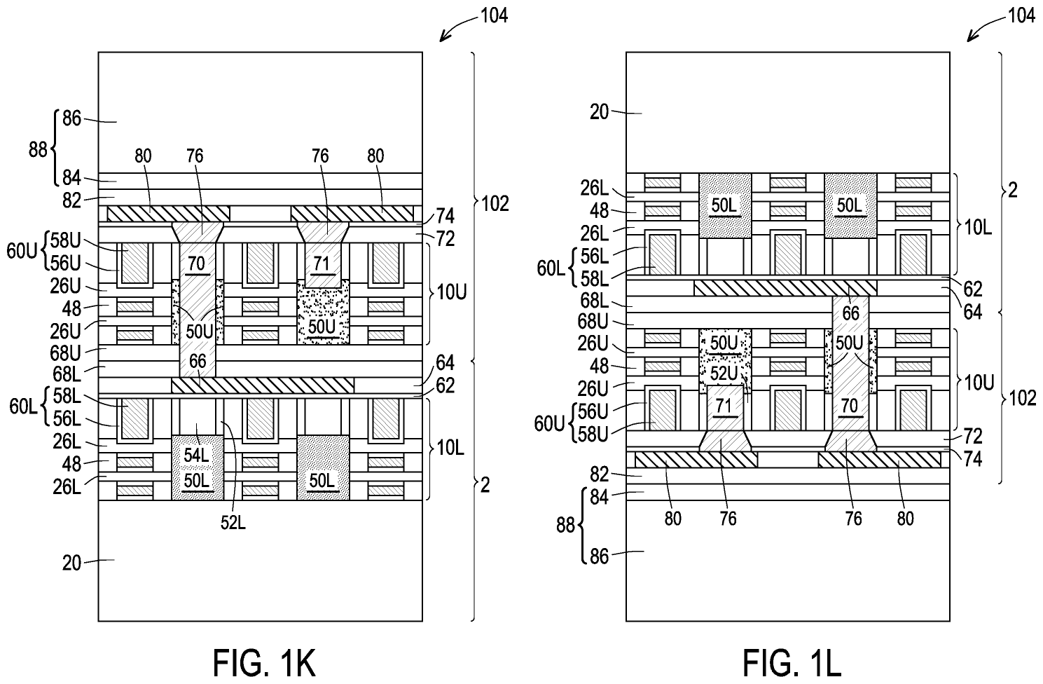

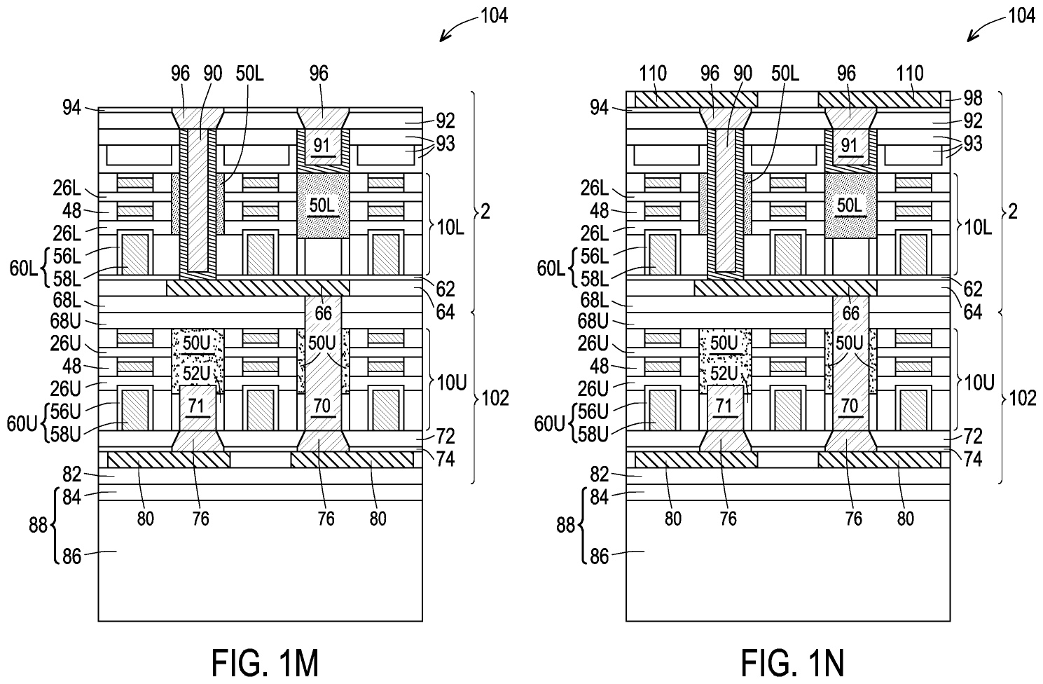

FIGS. 1A-1N, 2A-2G, 3A-3J, 4A-4L, 5A-5I, and 6A-6I illustrate the views of the formation of CFETs through sequential processes in accordance with some embodiments. In the sequential formation processes, lower transistors are formed first, followed by the formation of the upper transistors.

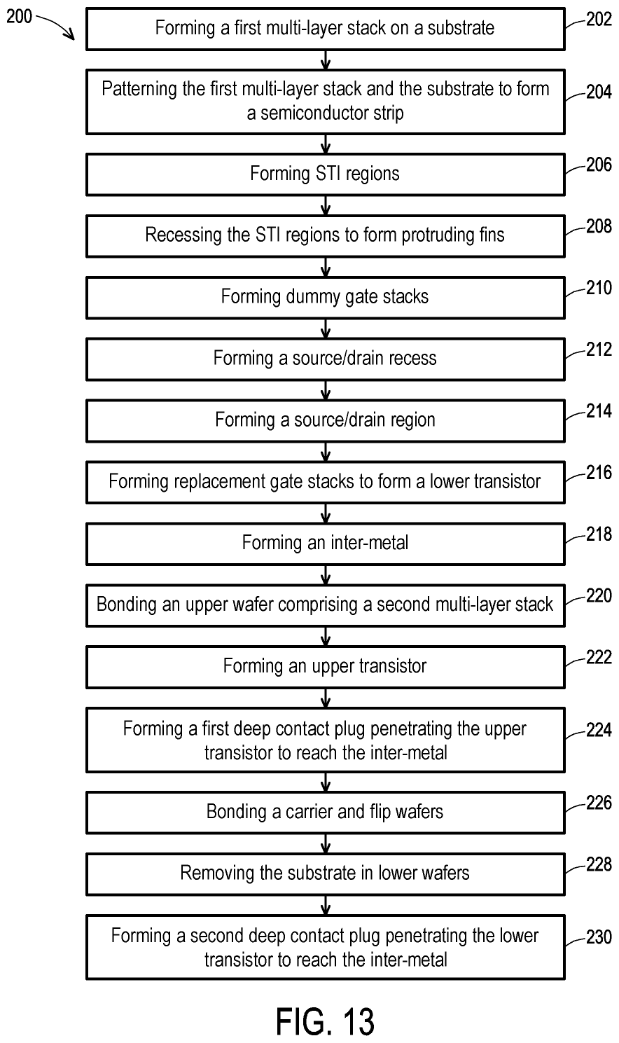

FIGS. 1A-1N illustrate the cross-sectional views of intermediate stages in the formation of CFETs and local interconnects in accordance with some embodiments of the present disclosure. The corresponding processes are also reflected schematically in the process flow 200 as shown in FIG. 13. The corresponding bonding process is also referred to as a face-to-back process since the front side (the face) of the bottom transistors (and the bottom die/wafer) is bonded to the backside of the upper transistors (and the upper die/wafer).

Referring to FIG. 1A, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. In accordance with some embodiments, the semiconductor material of the substrate 20 may include silicon, germanium, carbon-doped silicon, a III-V compound semiconductor; or the like, or combinations thereof.

A multi-layer stack 22L is formed over the substrate 20. The respective process is illustrated as process 202 in the process flow 200 as shown in FIG. 13. The multi-layer stack 22 includes alternating dummy semiconductor layers 24L and semiconductor layers 26L. Lower semiconductor layers 26L are for forming a lower transistor. Appropriate well regions (not separately illustrated) such as p-well regions and n-well regions may be formed in lower semiconductor nanostructures 26L. For example, semiconductor nanostructures 26L may be in-situ doped (when epitaxially grown) and/or implanted to n-type when the lower transistors to be formed are p-type transistors. Conversely, semiconductor nanostructures 26L may be of p-type when the lower transistors to be formed are n-type transistors.

In the illustrated example, two dummy semiconductor layers 24L and two semiconductor layers 26L are illustrated as an example, while the total numbers of these layers may be greater than 2, such as 3, 4, 5, or more, depending on the desirable performance requirement of the lower transistors. In accordance with some embodiments, the (top) surface orientation of semiconductor layers 26L is selected based on the type of the lower transistors, so that the performance of the lower transistors is improved. For example, when the lower transistors are p-type transistors, the (top) surface orientation may be (110). Conversely, when the lower transistors are n-type transistors, the (top) surface orientation may be (100).

The dummy semiconductor layers 24L may be formed of a first semiconductor material. The semiconductor layers 26L are formed of a second semiconductor material different from the first semiconductor material. In accordance with some embodiments, dummy semiconductor layers 24L are formed of or comprise silicon germanium, and semiconductor layers 26 may be formed of silicon.

Multi-layer stack 22L and substrate 20 are patterned to form semiconductor strips 28 as shown in FIG. 1B, which illustrates a perspective view. The respective process is illustrated as process 204 in the process flow 200 as shown in FIG. 13. Each of semiconductor strips 28 includes a semiconductor strip 20′ (the portions of the original substrate 20) and multi-layer stack 22L′, which is a remaining portion of multi-layer stack 22L. The layers in the remaining portions 22L′ may be referred to as nanostructures hereinafter. The etching may be performed by any acceptable etch process, such as a Reactive Ion Etch (RIE), Neutral Beam Etch (NBE), the like, or a combination thereof. The etching may be anisotropic. The remaining portions of the lower semiconductor nanostructures 26L will act as channel regions for the lower transistors of the CFETs.

Isolation regions 32 are formed over the substrate 20 and between adjacent semiconductor strips 28. The respective process is illustrated as process 206 in the process flow 200 as shown in FIG. 13. Isolation regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of isolation regions 32 may include depositing the dielectric layer(s), and performing a planarization process such as a Chemical Mechanical Polish (CMP) process, a mechanical polishing process, or the like to remove excess portions of the dielectric materials. The deposition processes may include chemical vapor deposition (CVD), atomic layer deposition (ALD), HDP-CVD, FCVD, the like, or a combination thereof. In accordance with some embodiments, the isolation regions 32 include silicon oxide formed by an FCVD process, followed by an anneal process.

After the planarization process, isolation regions 32 are recessed. Some upper portions of semiconductor strips 28 (including multi-layer stacks 22L′) protrude higher than the remaining isolation regions 32 to form protruding fins 34. The respective process is also illustrated as process 208 in the process flow 200 as shown in FIG. 13.

Dummy gate dielectric 36 is formed on the protruding fins 34. Dummy gate dielectric 36 may be formed of or comprise, for example, silicon oxide, silicon nitride, a combination thereof, or the like, and may be deposited or thermally grown according to acceptable techniques. A dummy gate layer 38 is formed over the dummy gate dielectric 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. One or more mask layer(s) 40 is formed over the planarized dummy gate layer 38, and may include, for example, silicon nitride, silicon oxynitride, or the like.

Next, the mask layer 40 may be patterned through photolithography and etching processes to form a mask, which is then used to etch and pattern dummy gate layer 38, and possibly dummy gate dielectric 36. A resulting structure is shown in FIG. 1C, which illustrates a vertical cross-section in FIG. 1B, which vertical cross-section is along the lengthwise direction of semiconductor strip 28. The remaining portions of mask layer 40, dummy gate layer 38, and dummy gate dielectric 36 form dummy gate stacks 42 as shown in FIG. 1C. The respective process is illustrated as process 210 in the process flow 200 as shown in FIG. 13.

Gate spacers 44 are then formed over the multi-layer stacks 22L′ and on the exposed sidewalls of dummy gate stacks 42. The gate spacers 44 may be formed by conformally depositing one or more dielectric layers and subsequently etching the dielectric layers in anisotropic etching processes. The applicable dielectric materials may include silicon oxide, silicon nitride, silicon oxynitride, silicon oxycarbonitride, or the like, which may be formed by a deposition process such as CVD, ALD, or the like.

Referring to FIG. 1D, source/drain recesses 46 are formed in semiconductor strips 28. The respective process is also illustrated as process 212 in the process flow 200 as shown in FIG. 13. The source/drain recesses 46 are formed through etching, and may extend through the multi-layer stacks 22L′, and may or may not extend into the semiconductor strips 20′. The bottom surfaces of the source/drain recesses 46 may be at a level above, below, or level with the top surfaces of the isolation regions 32 (not shown in FIG. 1D). In the etching processes, the gate spacers 44 and the dummy gate stacks 42 cover and hence protect some portions of the semiconductor strips 28. The etching may include a single etch process or multiple etch processes. Timed etch processes may be used to stop the etching of the source/drain recesses 46 upon source/drain recesses 46 reaching a desired depth.

In FIG. 1E, inner spacers 48 are formed. The formation of inner spacers 48 may include an etching process that laterally etches the dummy semiconductor layers 24L (FIG. 1D), and filling the respective lateral recesses with a dielectric material to form the inner spacers 48.

The etching process may be isotropic and may be selective to the material of the dummy semiconductor layers 24L, so that the dummy semiconductor layers 24L are etched at a faster rate than the semiconductor nanostructures 26L. In accordance with some embodiments in which the dummy nanostructures 24L are formed of silicon germanium or germanium, and the semiconductor nanostructures 26L are formed of silicon free from germanium, the etch process may comprise a dry etch process using chlorine gas, with or without a plasma.

Inner spacers 48 are formed on the sidewalls of the laterally recessed dummy semiconductor layers 24L. In the subsequent formation of source/drain regions, the inner spacers 48 may act as isolation features between the subsequently formed source/drain regions and the subsequently formed gate structures. Further, the inner spacers 48 may be used to prevent damage to the subsequently formed source/drain regions by subsequent etch processes, such as the etch processes used to form gate structures.

The formation of the inner spacers 48 may include conformally depositing a dielectric insulating material in the source/drain recesses 46, and then etching the dielectric insulating material. The dielectric insulating material may be a non-low-k dielectric material, which may be a carbon-containing dielectric material such as silicon oxycarbonitride, silicon oxycarbide, silicon oxynitride, or the like. The insulating material may be formed by a deposition process, such as ALD, CVD, or the like. The etching of the insulating material may be anisotropic or isotropic.

Further referring to FIG. 1E, lower epitaxial source/drain regions 50L are formed. The respective process is illustrated as process 214 in the process flow 200 as shown in FIG. 13. The lower epitaxial source/drain regions 50L are in contact with the lower semiconductor nanostructures 26L. Inner spacers 48 electrically insulate the lower epitaxial source/drain regions 50L from the dummy semiconductor layers 24L, which will be replaced with replacement gates in subsequent processes.

The lower epitaxial source/drain regions 50L are epitaxially grown, and have a conductivity type that is suitable for the device type (p-type or n-type) of the lower transistors. When lower epitaxial source/drain regions 50L are n-type source/drain regions, the respective material may include silicon or carbon-doped silicon, which is doped with an n-type dopant such as phosphorous, arsenic, and/or the like. When lower epitaxial source/drain regions 50L are p-type source/drain regions, the respective material may include silicon or silicon germanium, which is doped with a p-type dopant such as boron, indium, and/or the like. The lower epitaxial source/drain regions 50L may be in-situ doped, and may be, or may not be, implanted with the corresponding p-type or n-type dopants.

A first Contact Etch Stop Layer (CESL) 52L and a first Inter-Layer Dielectric (ILD) 54L are formed over the lower epitaxial source/drain regions 50L. In accordance with some embodiments, CESL 52L may include vertical portions (as illustrated) and horizontal portions (not shown) that are directly on the lower epitaxial source/drain regions 50L. In accordance with alternative embodiments, the horizontal portions of the CESL 52L are removed prior to the formation of the first ILD 54L.

The first CESL 52L may be formed of a dielectric material having a high etching selectivity from the etching of the first ILD 54L, such as silicon nitride, silicon oxide, silicon oxynitride, or the like, which may be formed by any suitable deposition process, such as CVD, ALD, or the like. The first ILD 54L may be formed of a dielectric material, which may be deposited by any suitable method, such as CVD, plasma-enhanced CVD (PECVD), or FCVD. The applicable dielectric material of the first ILD 54L may include phospho-silicate glass (PSG), boro-silicate glass (BSG), boron-doped phospho-silicate glass (BPSG), undoped silicate glass (USG), silicon oxide, or the like. The top surfaces of the first CESL 52L, the first ILD 54L, and the dummy gate stacks 42 (FIG. 1D) may be planarized by a planarization process, which may be a Chemical Mechanical Polish (CMP) process or a mechanical polishing process.

Further referring to FIG. 1E, replacement gate stacks 60L are formed, which include gate dielectrics 56L and gate electrodes 58L. The respective process is illustrated as process 216 in the process flow 200 as shown in FIG. 13. Gate dielectrics 56L may be conformally formed on the channel regions of the semiconductor nanostructures 26. Each of the gate dielectrics 56L may include an interfacial layer (IL), which may be formed of or comprise an oxide such as silicon oxide or a metal oxide, a silicate such as a metal silicate, combinations thereof, multi-layers thereof, or the like. Each of the gate dielectrics 56L may also include a high dielectric constant (high-k) dielectric layer formed of a high-k dielectric material having a k-value greater than 3.9, and possibly greater than about 7.0. The high-k dielectric material may comprise a metal oxide or a metal nitride of metals such as hafnium, aluminum, zirconium, lanthanum, manganese, barium, titanium, lead. The formation methods of the gate dielectrics 56L may include molecular-beam deposition (MBD), ALD, PECVD, and the like.

Further referring to FIG. 1E, lower gate electrodes 58L are formed on the gate dielectrics 56L, and also wrap around the lower semiconductor nanostructures 26L. Lower gate electrodes 58L may include adhesion layers, work-function layers, a filling metal, or the like. The materials of the work-function layers are selected based on the conductivity type of the respective transistor. For example, for an n-type transistor, n-type work function materials such as TiAl, TiAlN, or the like may be used to form the work-function layer. For a p-type transistor, p-type work function materials such as TiN may be used to form the work-function layer. Lower transistor 10L is thus formed.

FIG. 1F illustrates the formation of etch stop layer 62, dielectric layer 64, and metal line 66 in accordance with some embodiments. Metal line 66 is also referred to as an inter-metal since it is formed between the lower transistor 10L and the subsequently formed upper transistor. The respective process is illustrated as process 218 in the process flow 200 as shown in FIG. 13.

In accordance with some embodiments, etch stop layer 62 is formed of a dielectric material such as AlN, AIO, SiON, SiOC, SiCN, or the like, or multi-layers thereof. Etch stop layer 62 may be used to stop the etching from both the top side (when forming metal line 66) and the bottom side (when forming deep contact plug 90, FIG. 1M). In accordance with some embodiments, etch stop layer 62 may have a symmetric multi-layer structure, which may include a top layer and a bottom layer formed of a same material (such as an AlN, AlO, or AlON), and a middle layer between the top layer and the bottom layer, with the middle layer having a high etching selectivity from the top layer and the bottom layer. For example, the middle layer may be formed of SiOC, SiON, or the like. The symmetric structure will increase the ability of the etch stop layer 62 for stop etching when etching from both the top side and the bottom side.

Dielectric layer 64 may be formed of a dielectric material such as silicon oxide, PSG, BSG, BPSG, USG, or the like. Metal line 66 may be formed of copper, tungsten, nickel, TiN, Ti, Ta, TiN, or the like. For example, metal line 66 may have a damascene structure, which is formed by etching dielectric layer 64 (and stopping on etch stop layer 62), filling a conductive material into the respective trench, and performing a planarization process. Metal line 66 may include an adhesion layer (formed of Ti, TiN, Ta, TaN, or the like), and a metallic material such as copper on the adhesion layer.

Bond layer 68L is then deposited. In accordance with some embodiments, bond layer 68L is formed through a deposition process such as CVD, ALD, PECVD, or the like. A planarization process may be performed to level the top surface of bond layer 68L. In accordance with some embodiments, bond layer 68L is formed of or comprises a silicon-containing dielectric material selected from SiO, SiC, SiN, SiOC, SiON, SiOCN, SiCN, or the like. Wafer 2 is thus prepared for bonding.

Referring to FIG. 1G, wafer 102 is bonded to wafer 2. The respective process is illustrated as process 220 in the process flow 200 as shown in FIG. 13. Wafer 102 may include substrate 120, multi-layer stack 22U, and bond layer 68U. Multi-layer stack 22U includes alternating semiconductor layers 26U and dummy semiconductor layers 24U. The alternating layers of semiconductor nanostructures 26U and dummy semiconductor layers 24U may be epitaxially grown in a plurality of epitaxy processes, each forming one of semiconductor nanostructures 26U and dummy semiconductor layers 24A.

The materials and the formation processes of substrate 120 and multi-layer stack 22U may be essentially the same as that of substrate 20 and multi-layer stack 22L as shown in FIG. 1, and the details are not repeated herein. The top layer of multi-layer stack 22U may be a dummy semiconductor layer 24U, which may be formed of silicon germanium in accordance with some embodiments. Bond layer 68U is formed on multi-layer stack 22U, and may also be formed of or comprise a silicon-containing dielectric material such as silicon oxide, silicon nitride, silicon oxynitride, silicon oxycarbide, silicon oxy carbonitride, or the like.

Upper wafer 102 is flipped upside down, and is bonded to the underlying lower wafer 2 through the bonding of bond layer 68U to bond layer 68L. The resulting composite wafer is shown in FIG. 1G. The bonding of bond layer 68U to bond layer 68L may be achieved through fusion bonding, for example, with Si—O—Si bonds being formed to join bond layer 68U to bond layer 68L.

Next, substrate 120 is removed, for example, through a smart cut process (to remove a majority portion of substrate 120), a CMP process, a mechanical grinding process, and/or an anisotropic etching process. The top one of the dummy semiconductor layers 24U may act as an etch stop layer. Accordingly, after an etching process or a polishing process, the top one of the dummy semiconductor layers 24U is exposed.

Next, the top dummy semiconductor layer 24U is removed in an etching process, which may be anisotropic or isotropic. The etching is performed using an etching chemical (a gas or a wet etching solution) that etches dummy semiconductor layer 24U faster than etching semiconductor nanostructures 26U. Accordingly, the top one of semiconductor nanostructures 26U acts as the etch stop layer.

In subsequent processes, as shown in FIG. 1H, upper transistor 10U is formed, with the semiconductor nanostructures 26U forming the channels of upper transistors 10U. The respective process is illustrated as process 222 in the process flow 200 as shown in FIG. 13. The formation process may be essentially the same as the formation of lower transistor 10L, which formation processes have been discussed referring to FIGS. 1B through 1E, and the details are not repeated herein.

The upper transistor 10U may include inner spacers 48, source/drain regions 50U, CESL 52U, and ILD 54U. Furthermore, gate stacks 60U are formed, and include gate dielectrics 56U and gate electrodes 58U. Transistor 10U may have an opposite conductivity type than transistor 10L. The conductivity type of source/drain regions 50U may also be opposite to that of source/drain regions 50L.

It is appreciated that although both of the lower transistor 10L and upper transistor 10U are GAA transistors in the example embodiments as illustrated, each of them may also be a FinFET or a GAA transistor (such as a nanosheet transistor or a nanowire transistor) in any combination.

FIG. 1I illustrates the formation of deep contact plug 70, which acts as both of the source/drain contact plug and the deep via connecting to the metal line 66. The respective process is illustrated as process 224 in the process flow 200 as shown in FIG. 13. Contact plug 71 is also formed to connect to, and land on, source/drain region 50U. There may be source/drain silicide regions (not shown) formed between and contacting deep contact plug 70 and the respective source/drain region 50U, and between and contacting contact plug 71 and the respective source/drain region 50U.

In accordance with some embodiments, the formation of deep contact plug 70 may include etching ILD 54U and CESL 52U (if having a horizontal portion), and etching-through upper source/drain regions 50U to form a trench. Upper source/drain regions 50U may have portions remaining on the opposite sides of the respective opening, which remaining portions are the source/drain regions of the corresponding upper transistor 10U. Bond layers 68U and 68L are also etched-through to exposed metal line 66.

Next, deep contact plug 70 is formed in the respective trench. Deep contact plug 70 may be formed of a conductive material, which may be a metallic material such as tungsten, cobalt, copper, Ti, TiN, Ta, TaN, or the like, combinations thereof, and/or multi-layers thereof. Although not illustrated, source/drain silicide layers may be formed on the exposed portions of source/drain regions 50U before the formation of deep contact plug 70.

Over deep contact plug 70, an interconnect structure is formed, as shown in FIGS. 1I and 1.J. As shown in FIG. 1I, dielectric layers 72 and 74 are formed. Another etch stop layer (not shown) may (or may not) be formed between dielectric layers 72 and gate stacks 60U. In accordance with some embodiments, dielectric layer 72 comprises a low-k dielectric material, which may be a silicon-and-carbon containing dielectric material. Dielectric layer 74 may (or may not) act as an etch stop layer, and may be formed of or comprise AlN, AlO, SiOC, and/or the like, combinations thereof, and/or multi-layers thereof. Via 76 is formed in dielectric layer 72, and may (or may not) penetrate through dielectric layer 74.

FIG. 1.J illustrates the formation of dielectric layer 78 and metal lines 80. Dielectric layer 78 may also be formed of a low-k dielectric material or a non-low-k dielectric material such as silicon oxide, silicon nitride, silicon carbide, or the like, or combinations thereof. Metal lines 80 may be formed through a damascene process, and may include copper, tungsten, cobalt, nickel, or the like. Each of metal lines 80 may also comprise a diffusion barrier. It is appreciated that although one metal layer is illustrated, the illustrate metal layer and the vias 76 represent a plurality of metal layers and the vias, which collectively form the front-side interconnect structure of wafer 102. FIG. 1J further illustrates the formation of bond layer 82, which may be formed of a material selected from the same group of candidate materials of bond layers 68L and 68U, which material may be a silicon-containing dielectric material.

FIG. 1K illustrates the bonding of carrier 88 to bond layer 82. The respective process is illustrated as process 226 in the process flow 200 as shown in FIG. 13. In accordance with some embodiments, carrier 88 includes semiconductor substrate 86, which may be a silicon substrate in accordance with some embodiments. Bond layer 84 is formed on semiconductor substrate 86. Bond layer 84 may be formed through a deposition process or a thermal oxidation process, and may be formed of a material that is selected from the same group of candidate materials of bond layers 68L and 68U. The bonding of bond layer 84 to bond layer 82 may be through fusion bonding in accordance with some embodiments.

Next, the composite wafer 104, which now includes lower wafer 102, upper wafer 104, and carrier 88 is flipped upside down, and the resulting structure is shown in FIG. 1L. The respective process is also illustrated as process 226 in the process flow 200 as shown in FIG. 13.

Substrate 20 is then removed, for example, in a smart cut process (to remove a majority portion of substrate 20), a CMP process, a mechanical grinding process, and/or an anisotropic etching process. Lower transistor 10L is thus exposed. The respective process is illustrated as process 228 in the process flow 200 as shown in FIG. 13. The resulting structure is shown in FIG. 1M.

FIG. 1M further illustrates the formation of deep contact plug 90. The respective process is also illustrated as process 230 in the process flow 200 as shown in FIG. 13. In accordance with some embodiments, the formation process includes etching-through source/drain region 50L, CESL 52L (if having the horizontal portion), and ILD 54L (FIG. 1L), and filling a conductive material(s) in the resulting opening to form deep contact plug 90. In the etching of ILD 54L, the etch process may be stopped on etch stop layer 62, followed by etching-through etch stop layer 62 in another etching process, which uses an etchant different from the etchant for etching ILD 54L.

In accordance with some embodiments, the source/drain regions 50L (FIG. 1L) may have portions remaining on the opposite sides of deep contact plug 90. The corresponding structure is essentially the same as source/drain region 50U, which has some portions remaining on the opposing sides of deep contact plug 70. In accordance with these embodiments, source/drain silicide regions (not shown) may be formed on the remaining portions of source/drain regions 50L, and physically separate (but electrically interconnect) the remaining portions of source/drain regions 50L from the deep contact plug 90. Accordingly, metal line 66 (the inter-metal) may electrically connect source/drain regions 50L to source/drain regions 50U.

In accordance with alternative embodiments, deep contact plug 90 has its edge contacting the sidewalls of inner spacers 48 and semiconductor nanostructures 26L. There may also be a dielectric liner (not shown) formed encircling contact plug 90 and electrically insulate contact plug 90 from semiconductor nanostructures 26L in accordance with these embodiments.

After the formation of deep contact plug 90, dielectric layers 93 are formed. Dielectric layers 93 may include etch stop layers and low-k dielectric layers in accordance with some embodiments. Contact plug 91 is also formed in dielectric layers 93, and is over and electrically connected to one of source/drain regions 50L. A silicide layer (not shown), may be formed underlying contact plug 91 and over source/drain regions 50L.

Over deep contact plug 90 and contact plug 91, an interconnect structure is formed, as shown in FIGS. 1M and 1N. As shown in FIG. 1M, dielectric layers 92 and 94 are formed. Another etch stop layer (not shown) may also be formed between dielectric layers 92 and 93. In accordance with some embodiments, dielectric layer 92 comprises a low-k dielectric material, which may be a silicon-and-carbon containing dielectric material. Dielectric layer 94 may (or may not) act as an etch stop layer, and may be formed of or comprise AlN, AlO, SiOC, and/or the like, combinations thereof, and/or multi-layers thereof. Vias 96 are formed in dielectric layer 92, and may (or may not) penetrate through dielectric layer 94.

FIG. 1N illustrates the formation of dielectric layer 98 and metal lines 110. Dielectric layer 98 may also be formed of a low-k dielectric material. Metal lines 110 may be formed through a damascene process, and may include copper, tungsten, nickel, or the like. Each of metal lines 110 may also comprise a diffusion barrier. It is appreciated that although one metal layer is illustrated, the illustrated metal layer represents a plurality of metal layers and the connecting vias, which collectively form the backside interconnect structure of wafer 2.

In subsequent processes, more layers/features may be formed, and the resulting composite wafer 104 may be sawed into dies. In the resulting dies obtained from the singulated composite wafer 104 as shown in 1N, the lower transistor 10L is illustrated over upper transistor 10U. Metal line 66 connects to the source/drain region 50U in transistor 10U, and may form a part of a local interconnect structure that connects source/drain region 50U to the source/drain region 50L (if remaining).

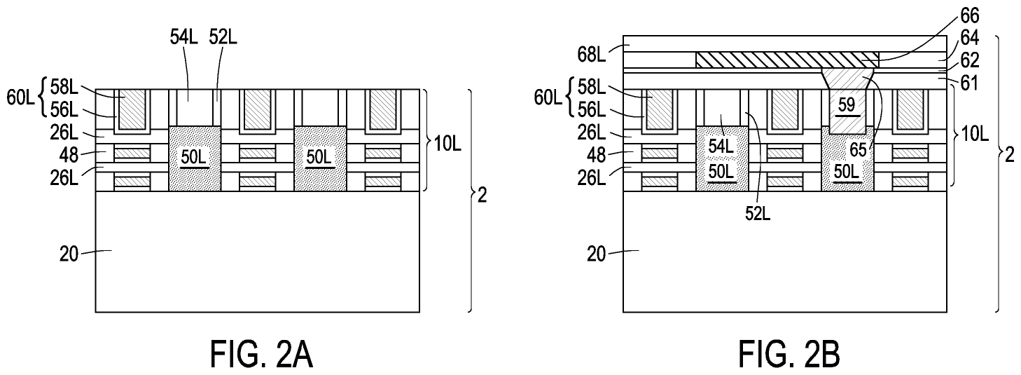

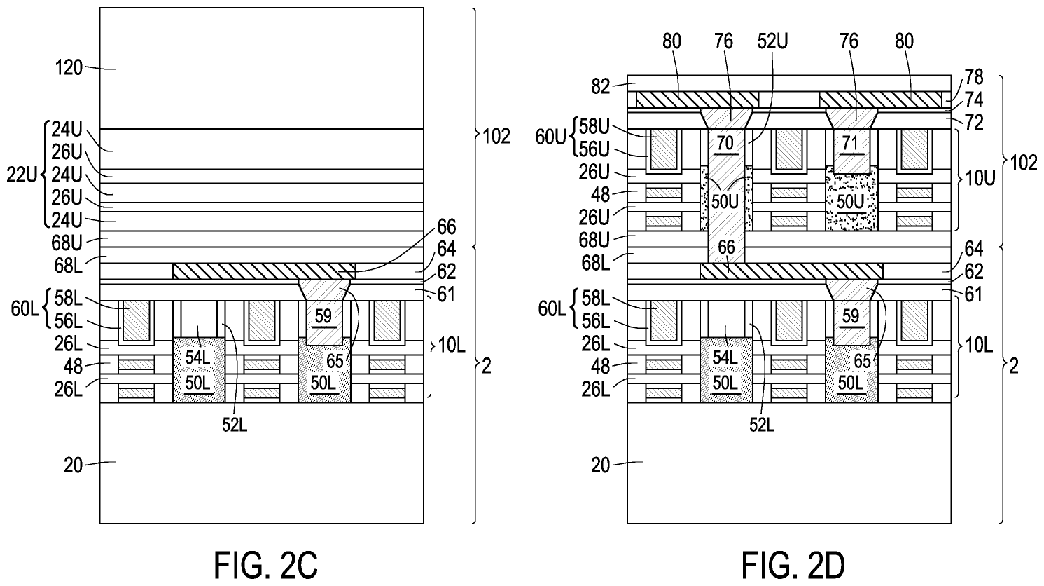

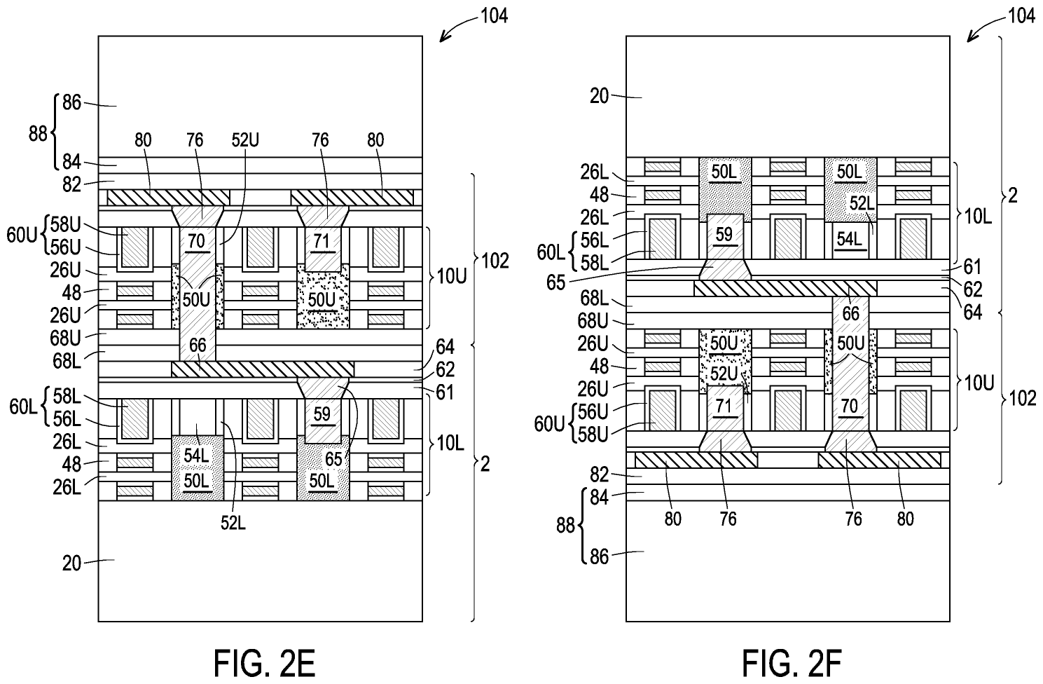

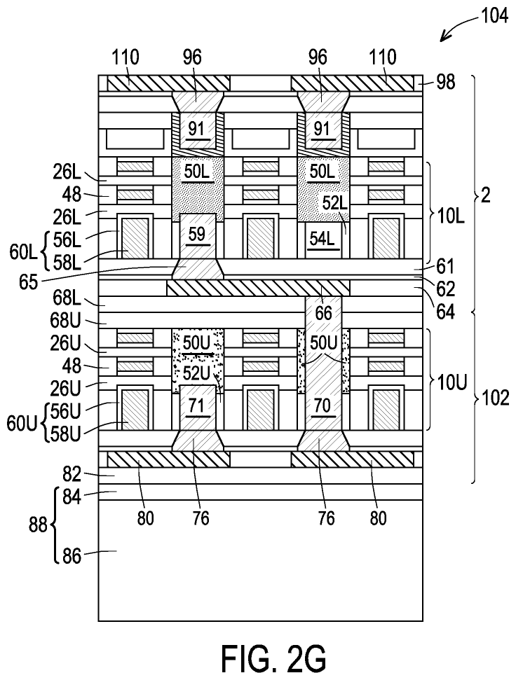

FIGS. 2A-2G illustrate the cross-sectional views of intermediate stages in the formation of CFETs and local interconnects in accordance with alternative embodiments of the present disclosure. The corresponding bonding process is also referred to as a face-to-back process since the front side (the face) of the bottom transistors (and the bottom die/wafer) is bonded to the backside of the upper transistors (and the upper die/wafer).

Unless specified otherwise, the materials, the structures, and the formation processes of the components in these embodiments (and the subsequently discussed embodiments) are essentially the same as the like components denoted by like reference numerals in the preceding embodiments. The details regarding the materials, the structures, and the formation processes provided in any of the embodiments throughout the description may be applied to any other embodiment whenever applicable. Also, the materials, the structures, and the formation processes in FIGS. 2A-2G and the subsequent processes may be realized from the discussion of the discussed embodiments.

The initial processes of these embodiments are essentially the same as shown in FIGS. 1A through 1E. FIG. 2A illustrates a structure that is the same as the structure shown in FIG. 1E, in which transistor 10L is formed. In accordance with some embodiments, transistor 10L includes semiconductor nanostructures 26L forming the channels, source/drain regions 50L, and gate stacks 60L wrapping around the semiconductor nanostructures 26L.

Referring to FIG. 2B, dielectric layers 62 and 64, metal line 66 (the inter-metal), and bond layer 68L are formed. The structures, materials and the formation processes of dielectric layers 62 and 64, metal line 66, and bond layer 68L are essentially the same as what have been discussed referring to FIG. 1F, and are not repeated herein.

Different from the structure as shown in FIG. 1F, source/drain contact plug 59 is formed during an early stage (rather than in the process shown in FIG. 1M) to extend into CESL 52L and ILD 54L, and is electrically connected to source/drain region 50L. Although not shown, a source/drain silicide region may be formed between source/drain region 50L and source/drain contact plug 59. In addition, dielectric layer 61 is formed, and via 65 is formed in dielectric layer 61 to electrically connect source/drain contact plug 59 and source/drain region 50L to metal line 66. Dielectric layer 61 may be formed of silicon oxide, silicon nitride, PSG, BSG, BPSG, USG, a low-k dielectric material, or the like. As a comparison, in the structure shown in FIG. 1F, metal line 66 is electrically decoupled from source/drain region 50L at this stage.

FIG. 2C illustrates the bonding of upper wafer 102 to lower wafer 2. Upper wafer 102 may be essentially the same as discussed in preceding embodiments. Upper wafer 102 may include semiconductor substrate 120, and alternating semiconductor layers 26U and dummy semiconductor layers 24U. The bonding may be achieved by bonding bond layer 68U in the upper wafer 102 to the bond layer 68L in lower wafer 2.

Next, as shown in FIG. 2D, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L.

Furthermore, deep contact plug 70 is formed to connect to metal line 66 and source/drain region 50U. Contact plug 71 is also formed to land on and electrically connect to another source/drain region 50U. Vias 76 and metal lines 80 are also formed to electrically connect to deep contact plug 70 and contact plug 71. Vias 76 and metal lines 80 are formed in dielectric layers 72, 74, and 78. Bond layer 82 is also formed, and may be planarized.

FIG. 2E illustrates the bonding of carrier 88 to bond layer 82 to form composite wafer 104. The resulting composite wafer 104 is then flipped upside down, and the resulting structure is shown in FIG. 2F. Substrate 20 is then removed, for example, in a smart cut process (to remove a majority portion of substrate 20), a CMP process, a mechanical grinding process, and/or an anisotropic etching process. Lower transistor 10L is thus exposed. The resulting structure is shown as a part of the structure in FIG. 2G.

FIG. 2G further illustrates the formation of additional features including source/drain contact plugs 91, and a backside interconnect structure on the backside of wafer 2. Although not illustrated, there may be metal silicide regions formed between source/drain contact plugs 91 and source/drain regions 50L. The backside interconnect structure includes vias 96 and metal lines 110, and the corresponding dielectric layers including dielectric layer 98. While the backside interconnect structure has one metal layer and the underlying vias illustrated in an example, the backside interconnect structure may include a plurality of metal layers and the connecting vias.

In subsequent processes, more layers/features may be formed, and the resulting composite wafer 104 may be sawed into dies. In the resulting dies obtained from the singulated composite wafer 104, source/drain contact plugs 91 are electrically connected to source/drain regions 50U through source/drain regions 50L, metal line 66, and deep contact plug 70. Differing from the embodiments in FIG. 1N, in which both of the source/drain regions 50L and 50U are penetrated-through in order to provide the electrical paths through them, one of source/drain regions 50L is used to provide through-interconnection. Metal line 66, via 65, and a part of deep contact plug 70 thus collectively form parts of the local interconnect for interconnecting.

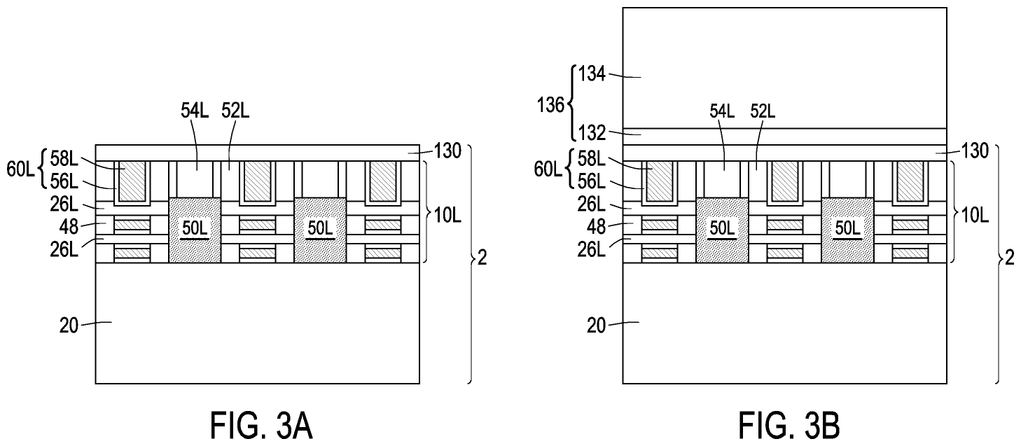

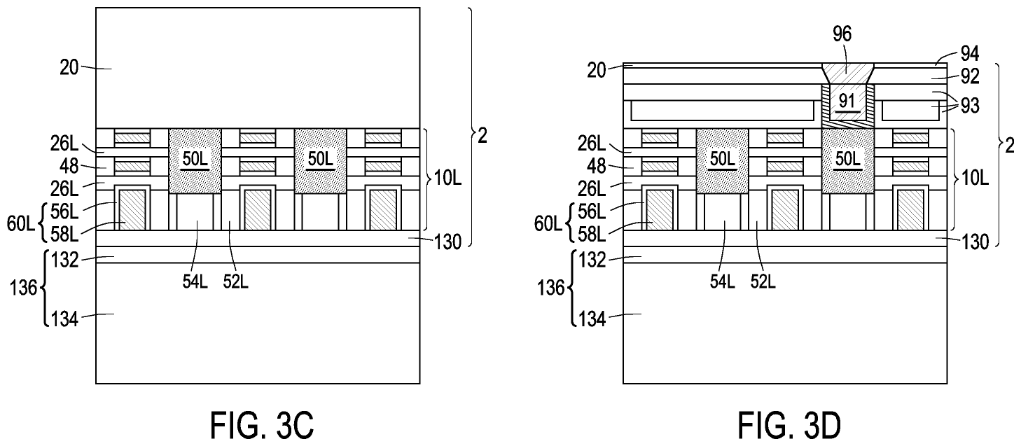

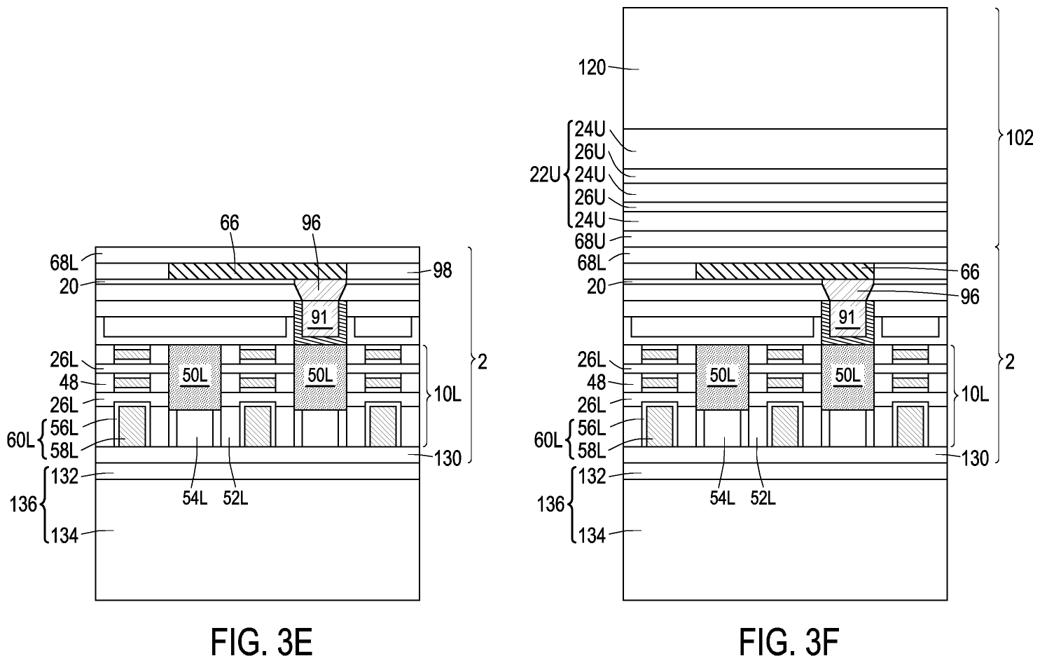

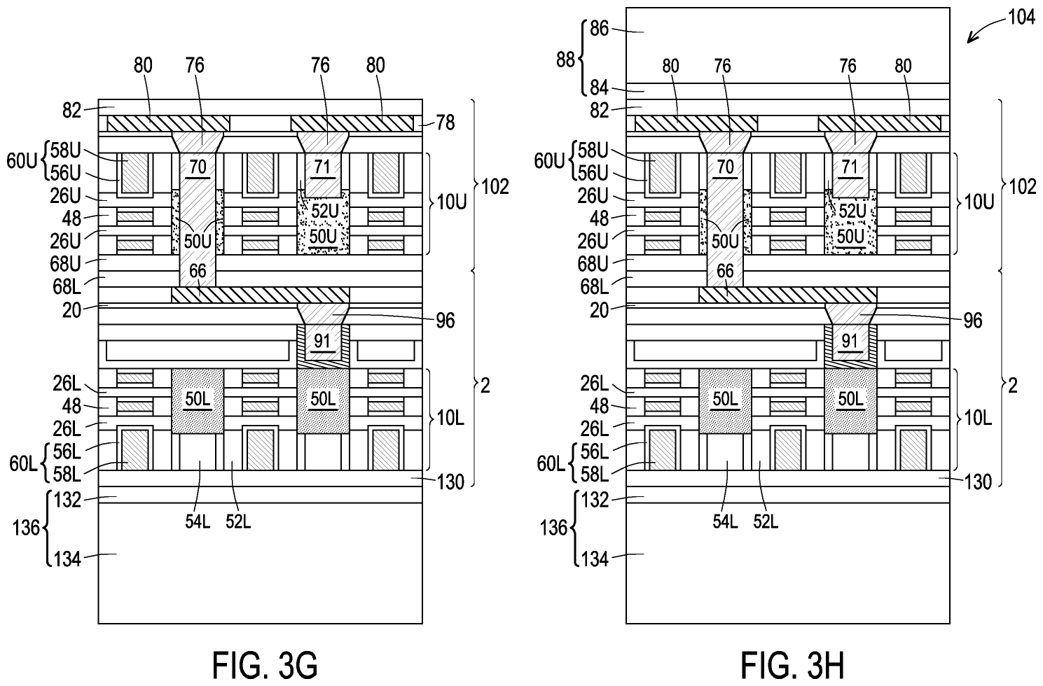

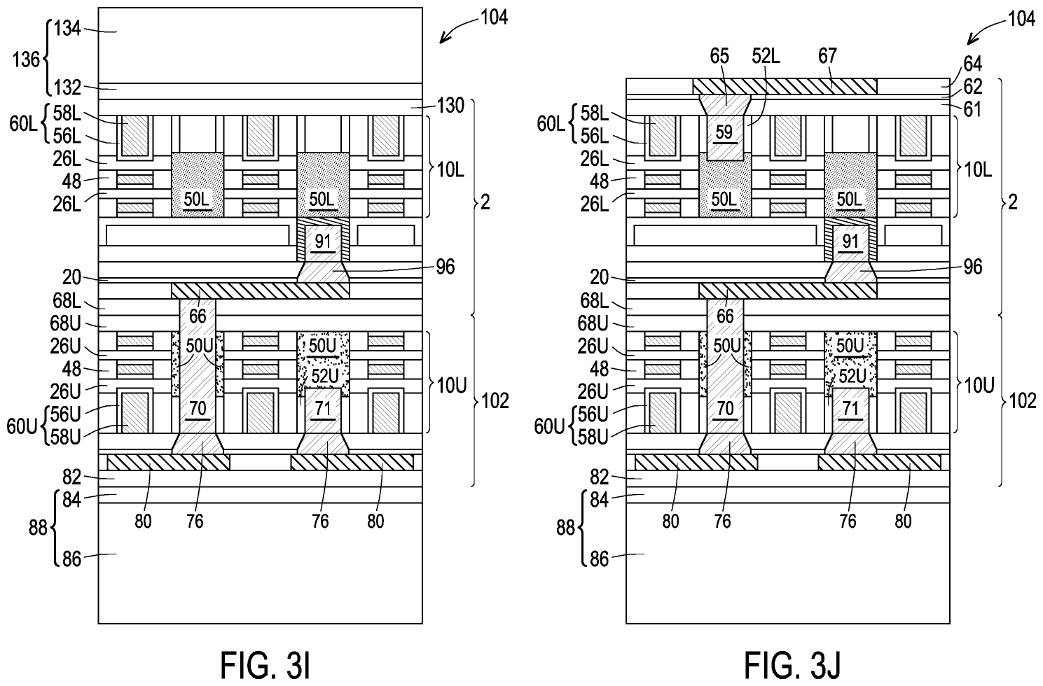

FIGS. 3A-3J illustrate the cross-sectional views of intermediate stages in the formation of CFETs and local interconnects in accordance with alternative embodiments of the present disclosure. The corresponding bonding process is also referred to as a back-to-back process since the backside of the bottom transistors (and the bottom die/wafer) is bonded to the backside of the upper transistors (and the upper die/wafer).

These processes are essentially the same as the processes shown in preceding figures, except that before bonding an upper wafer to a lower wafer, a carrier is attached to the front side of the lower wafer, and the original substrate of the lower wafer is removed.

The initial processes of these embodiments are essentially the same as shown in FIGS. 1A through 1E. FIG. 3A illustrates a structure that is the same as the structure shown in FIG. 1E. In accordance with some embodiments, transistor 10L includes semiconductor nanostructures 26L forming the channels, source/drain regions 50L, and gate stacks 60L wrapping around the semiconductor nanostructures 26L.

FIG. 3A further illustrates the formation of bond layer 130 as a part of the lower wafer 2. Bond layer 130 is bonded to the front side of wafer 2, and may be in contact with gate stacks 60L. The bond layer 130 may be a silicon-containing dielectric layer, which may include SiO, SiC, SiN, SiCN, SiOC, SiOCN, SiON, or the like. In accordance with some embodiments, bond layer 130 is planarized to have a planar top surface.

FIG. 3B illustrates the bonding of carrier 136 to wafer 2 through bonding to bond layer 130. In accordance with some embodiments, carrier 136 includes semiconductor substrate 134, which may be a silicon substrate. Bond layer 132 is formed on semiconductor substrate 134 in accordance with these embodiments. Bond layer 132 may be formed through a deposition process or a thermal oxidation process, and may be formed of a material that is selected from the same group of candidate materials of bond layer 130. The bonding of bond layer 132 to bond layer 130 may be through fusion bonding in accordance with some embodiments.

In accordance with alternative embodiments, carrier 136 includes a transparent substrate (also denoted using reference numeral 134) such as a glass substrate, which is attached to lower wafer 2 through an adhesive such as a light-to-heat-Conversion (LTHC) material (also denoted using reference numeral 132), which is configured to be decomposed under the heat of light (such as a laser beam). The structure including lower wafer 2 and carrier 136 is then flipped upside down, and the resulting structure is shown in FIG. 3C.

Substrate 20 is then removed, for example, in a smart cut process (to remove a majority portion of substrate 20), a CMP process, a mechanical grinding process, and/or an anisotropic etching process. Lower transistor 10L is thus exposed. The resulting structure is shown as being a lower part of the structure in FIG. 3D.

FIG. 3D further illustrates the formation of contact plug 91, via 96, and a plurality of dielectric layers 93, 92, and 94. Another etch stop layer (not shown) may also be formed between dielectric layers 92 and 93. In accordance with some embodiments, dielectric layer 92 comprises a low-k dielectric material, which may be a silicon-and-carbon containing dielectric material. Dielectric layer 94 may (or may not) act as an etch stop layer, and may be formed of or comprise AlN, AlO, SiOC, and/or the like, combinations thereof, and/or multi-layers thereof. Via 96 is formed in dielectric layer 92, and may (or may not) penetrate through dielectric layer 94.

FIG. 3E illustrates the formation of dielectric layer 98 and metal line 66, which is electrically connected to source/drain region 50L through via 96 and contact plug 91. Bond layer 68L is then formed, which may be formed of a silicon-containing dielectric material such as SiO, SiN, SiC, SiCN, SiOCN, or the like.

Next, referring to FIG. 3F, upper wafer 102 is bonded to lower wafer 2. Upper wafer 102 may be essentially the same as discussed in preceding embodiments. Upper wafer 102 may include semiconductor substrate 120, and alternating semiconductor layers 26U and dummy semiconductor layers 24U. The bonding may be achieved by bonding bond layer 68U to bond layer 68L.

Next, as shown in FIG. 3G, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L.

Further referring to FIG. 3G, deep contact plug 70 and contact plug 71 are formed to connect to metal line 66 and source/drain region 50U, respectively. Vias 76 and metal lines 80 are also formed, which are in dielectric layers 72, 74, and 78. Bond layer 82 is also formed, and may be planarized. In accordance with some embodiments, bond layer 82 is formed of or comprises a silicon-containing dielectric material such as SiO, SiN, SiN, SiON, SiCN, SiOCN, or the like, combinations thereof, and/or multi-layers thereof. In accordance with alternative embodiments, instead of forming a bond layer, a buffer layer (also referred to as bond layer 82) may be formed, and may comprise a polymer such as polyimide or Polybenzoxazole (PBO).

FIG. 3H illustrates the bonding of carrier 88 to bond layer 82, hence forming composite wafer 104. The resulting composite wafer 104 is then flipped upside down, and the resulting structure is shown in FIG. 3I. Carrier 136 is then removed, for example, in a CMP process, a mechanical grinding process, or an etching process when carrier 136 comprises a semiconductor substrate. When carrier 136 is a glass carrier adhered to the underlying structure through an LTHC 132, a laser beam may be used to decompose LTHC 132, thus de-bonding carrier 136.

FIG. 3.J illustrates the formation of additional features including source/drain contact plugs 91, and an interconnect structure including via 65 and metal line 67, and the corresponding dielectric layers. In subsequent processes, more layers/features may be formed, and the resulting composite wafer 104 may be sawed into dies. In the resulting dies obtained from the singulated composite wafer 104, metal line 66 acts as a part of the local interconnect for interconnecting source/drain regions 50L and 50U.

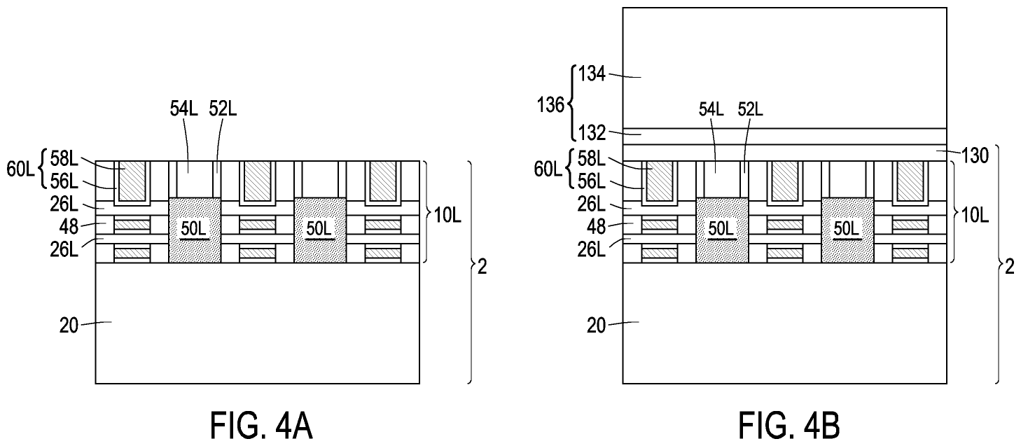

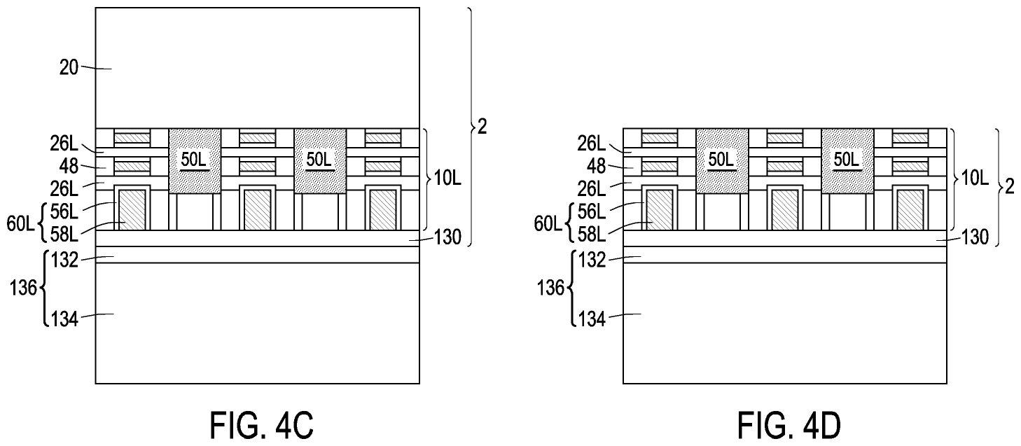

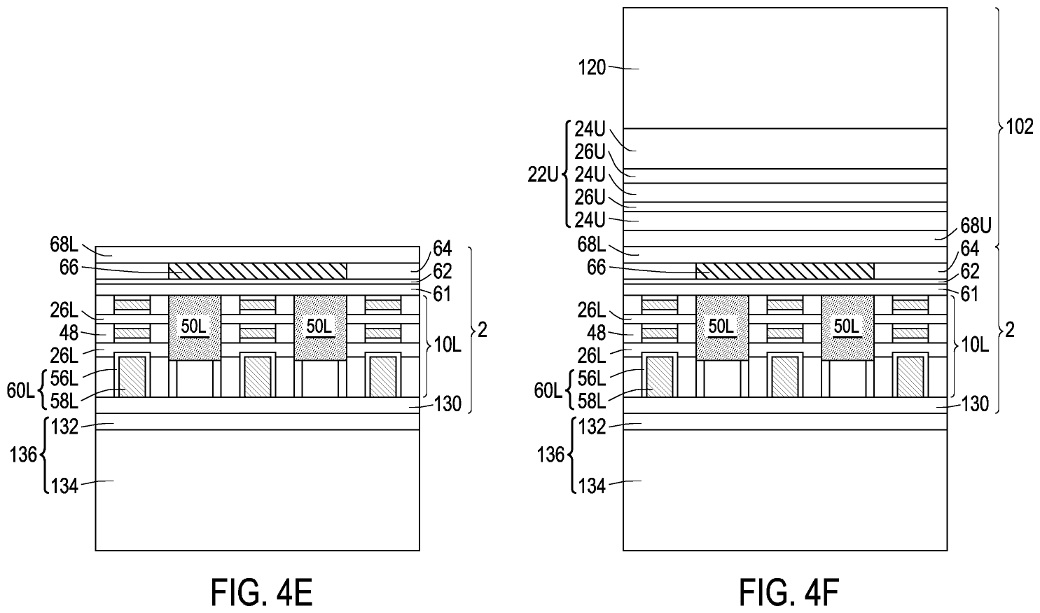

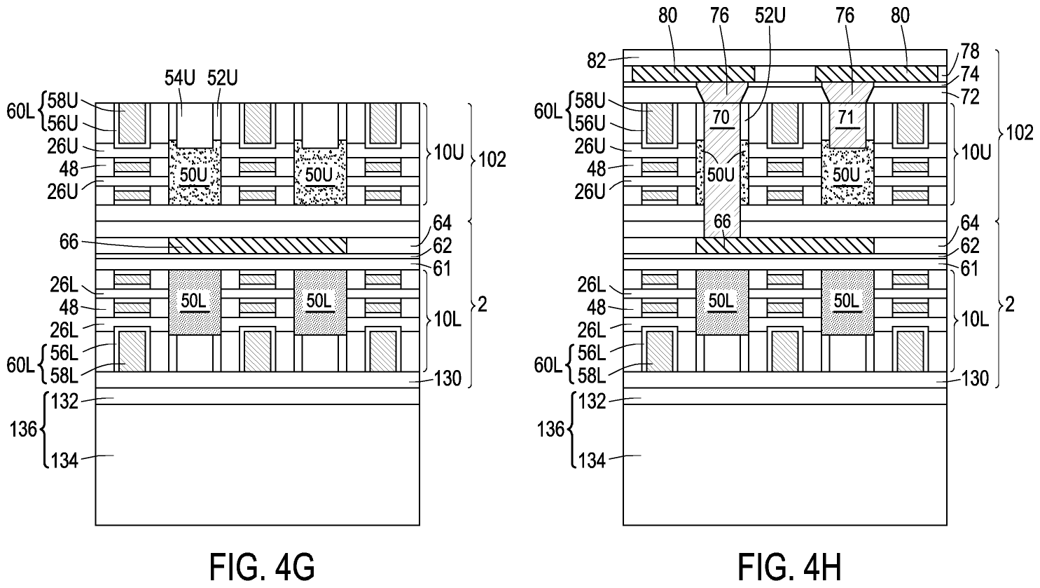

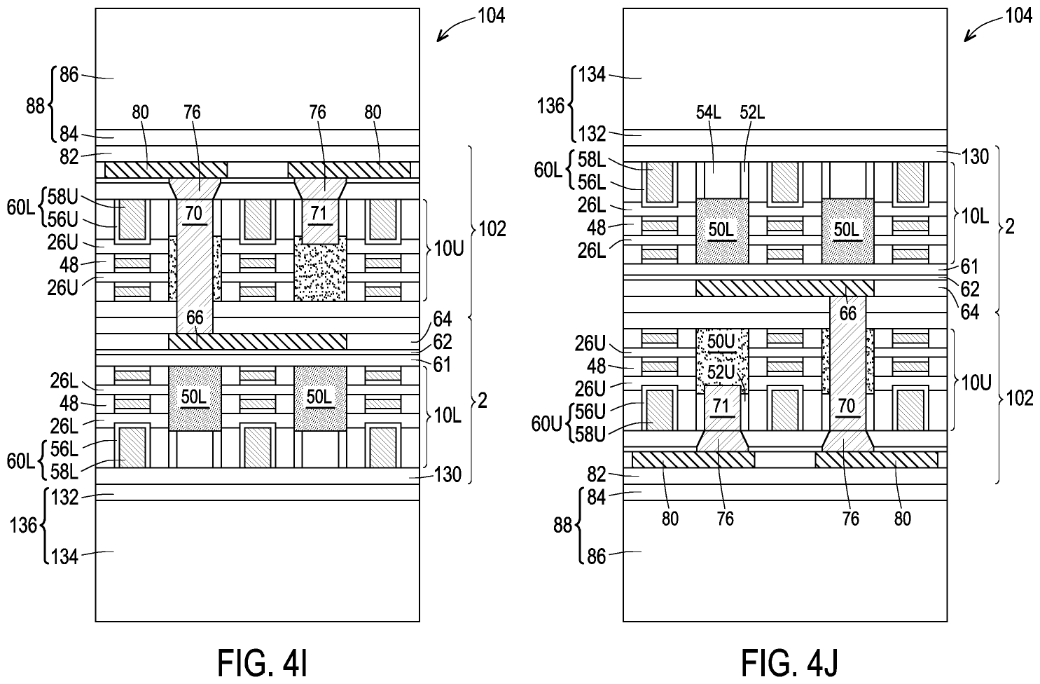

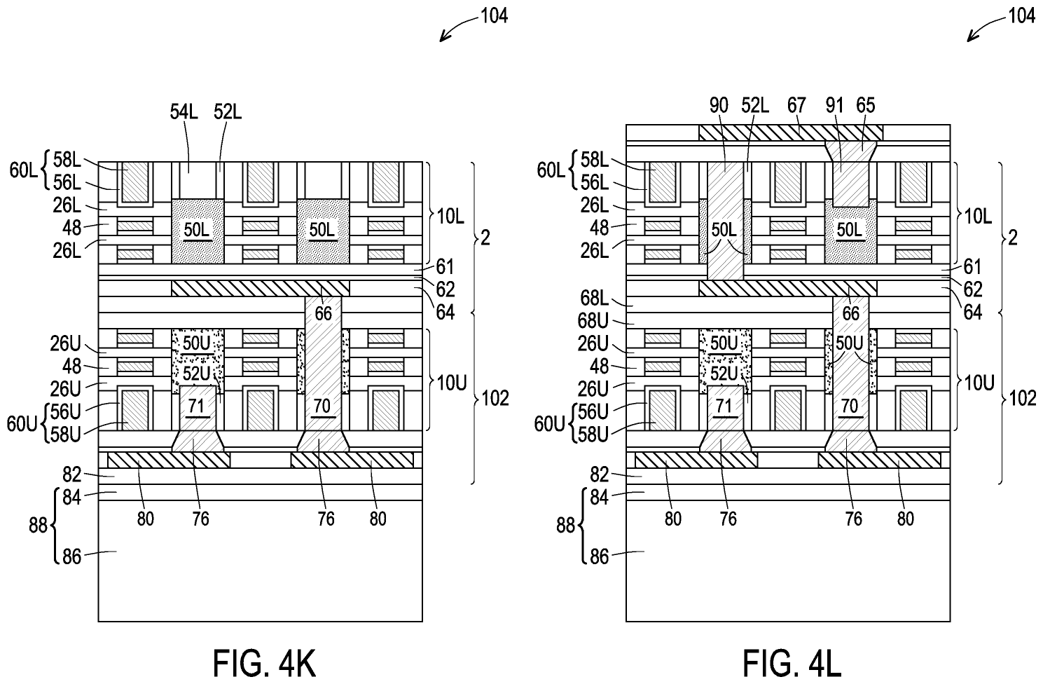

FIGS. 4A-4L illustrate the cross-sectional views of intermediate stages in the formation of CFETs and local interconnects in accordance with alternative embodiments of the present disclosure. The corresponding bonding process is also referred to as a back-to-back process since the backside of the bottom transistors (and the bottom die/wafer) is bonded to the backside of the upper transistors (and the upper die/wafer).

These processes are essentially the same as the processes shown in FIGS. 3A-3J, except that the connection from source/drain regions 50L to metal line 66 is formed after the formation of transistor 10U (and in FIG. 4L), rather than in a step (FIG. 3D) that is performed before the bonding of upper wafer to the bottom wafer.

The processes shown in FIGS. 4A, 4B, and 4C are the same as the processes shown in FIGS. 3A, 3B, and 3C, respectively, in which transistor 10L is formed. In accordance with some embodiments, transistor 10L includes semiconductor nanostructures 26L forming the channels, source/drain regions 50L, and gate stacks 60L wrapping around the semiconductor nanostructures 26L. As also shown in FIG. 4C, carrier 136 is attached, with substrate 134 being a semiconductor substrate (such as a silicon substrate) or a glass carrier, and layer 132 being a bond layer or an LTHC.

The processes shown in FIGS. 4D and 4E are similar to the processes shown in FIGS. 3D and 3E, in which dielectric layers 61 and 64 are formed, and metal line 66 is formed in dielectric layer 64. Etch stop layer 61 may also be formed to stop the etching for forming metal line 66. At this stage, metal line 66 (the inter-metal) is electrically decoupled from source/drain regions 50L. Rather, the connection of source/drain regions 50L to metal line 66 will be formed after upper transistors are formed.

FIG. 4E further illustrates the formation of bond layer 68L as a part of the lower wafer 2. bond layer 68L is formed on the front side of wafer 2, and may be in contact with gate stacks 60L. The material of bond layer 68L may be a silicon-containing dielectric material, which may include SiO, SiC, SiN, SiCN, SiOC, SiOCN, SiON, or the like. In accordance with some embodiments, bond layer 68L is planarized to have a planar top surface.

Next, referring to FIG. 4F, upper wafer 102 is bonded to lower wafer 2. Upper wafer 102 is essentially the same as discussed in preceding embodiments. Upper wafer 102 may include semiconductor substrate 120, and alternating semiconductor layers 26U and dummy semiconductor layers 24U. The bonding may be achieved by bonding bond layer 68U to bond layer 68L.

Next, as shown in FIG. 4G, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L.

Referring to FIG. 4H, deep contact plug 70 and contact plug 71 are formed to connect to metal line 66 (and one of source/drain regions 50U) and source/drain region 50U, respectively. Vias 76 and metal lines 80 are also formed, which are in dielectric layers 72, 74, and 78. Bond layer 82 is also formed, and may be planarized.

FIG. 4I illustrates the bonding of carrier 88 to bond layer 82. Carrier 88 may include semiconductor substrate 86 (such as a silicon substrate), and bond layer 84 bonding to bond layer 82, thus forming composite wafer 104. The resulting composite wafer 104 is then flipped upside down, and the resulting structure is shown in FIG. 4J.

Carrier 136 is then removed. The resulting structure is shown in FIG. 4K. When carrier 136 is a glass carrier adhered to the underlying structure through an LTHC 132, a laser beam may be used to decompose LTHC 132, thus de-bond carrier 136. Otherwise, when substrate 134 is a semiconductor substrate, substrate 134 may be removed in a smart cut process, a CMP process, a mechanical grinding process, and/or an anisotropic etching process.

FIG. 4L illustrates the formation of deep contact plug 90, which acts as both of the source/drain contact plug and the deep via connecting the metal line 66. Deep contact plug 90 penetrates through the respective source/drain region 50L. Contact plug 91 is also formed to connect to one of source/drain regions 50L. There may be source/drain silicide regions (not shown) formed between contact plug 91 and source/drain region 50L.

The formation of deep contact plug 90 may also include etching ILD 54L, CESL 52L (when comprising the horizontal portion), source/drain region 50L, and dielectric layer 61. The etching is stopped on etch stop layer 62. Another etching process is used to etch-through etch stop layer 62 and to reveal metal line 66. The etching chemical used for etching the etch stop layer 62 may be different from what is used for etching dielectric layer 61. The resulting trench is then filled with conductive materials to form deep contact plug 90. Although not illustrated, source/drain silicide layers may be formed between, and contacting upper source/drain region 50U and deep contact plug 90. Source/drain region 50L is thus electrically connected to source/drain region 50U through metal line 66, which acts as an inter-metal between transistors 10L and 10U.

Over deep contact plug 90 and contact plug 91, an interconnect structure is formed. FIG. 4L illustrates the formation of a plurality of dielectric layers, via 65, and metal line 67. The dielectric layers may also be formed of low-k dielectric materials. Metal lines 67 may be formed through a damascene process, and may include copper, tungsten, nickel, or the like. Metal line 67 may also comprise a diffusion barrier. It is appreciated that although one metal layer is illustrated, the illustrated metal layer represents a plurality of metal layers, which collectively form the front-side interconnect structure of wafer 2.

In subsequent processes, more layers/features may be formed, and the resulting composite wafer 104 may be sawed into dies. In the resulting dies obtained from the singulated composite wafer 104, metal line 66 acts as a part of the local interconnect for interconnecting source/drain regions 50L and 50U.

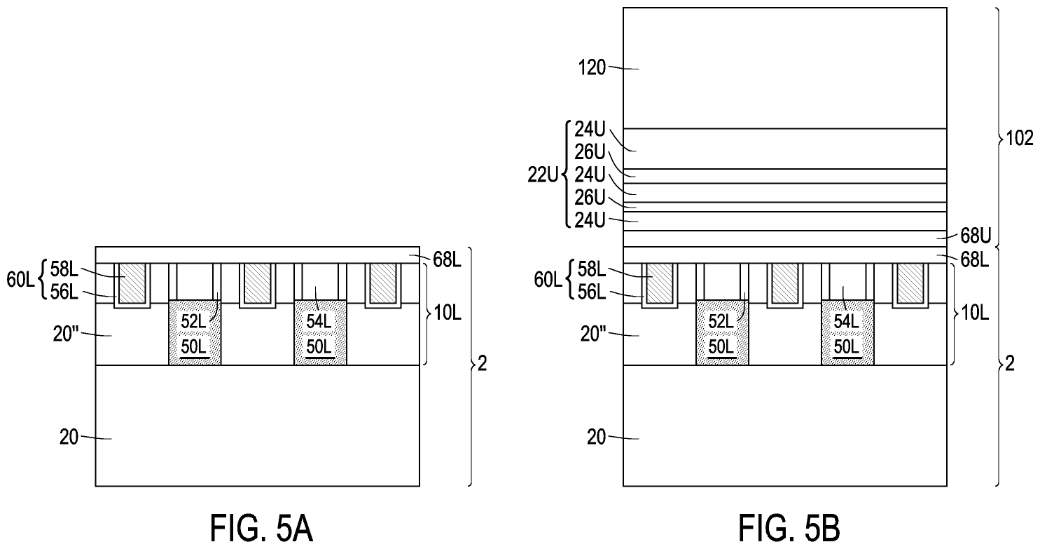

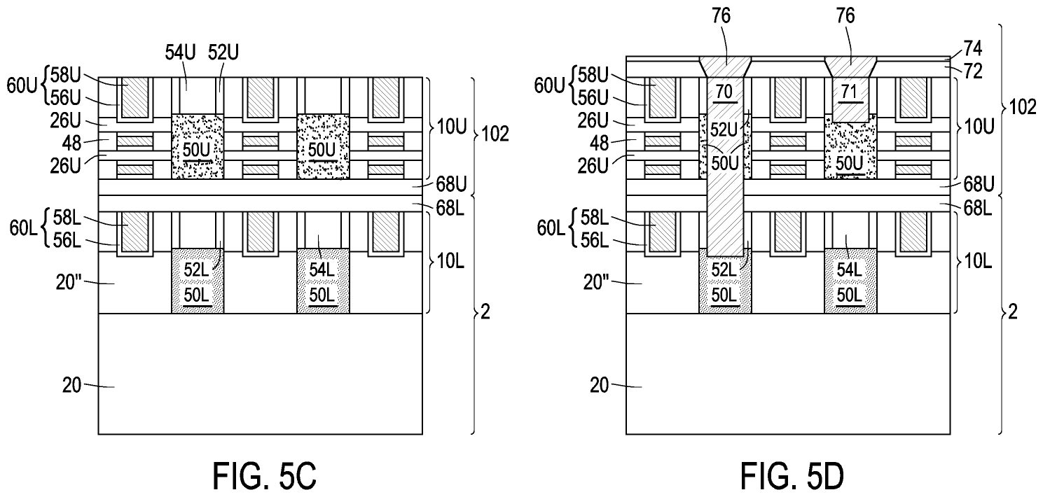

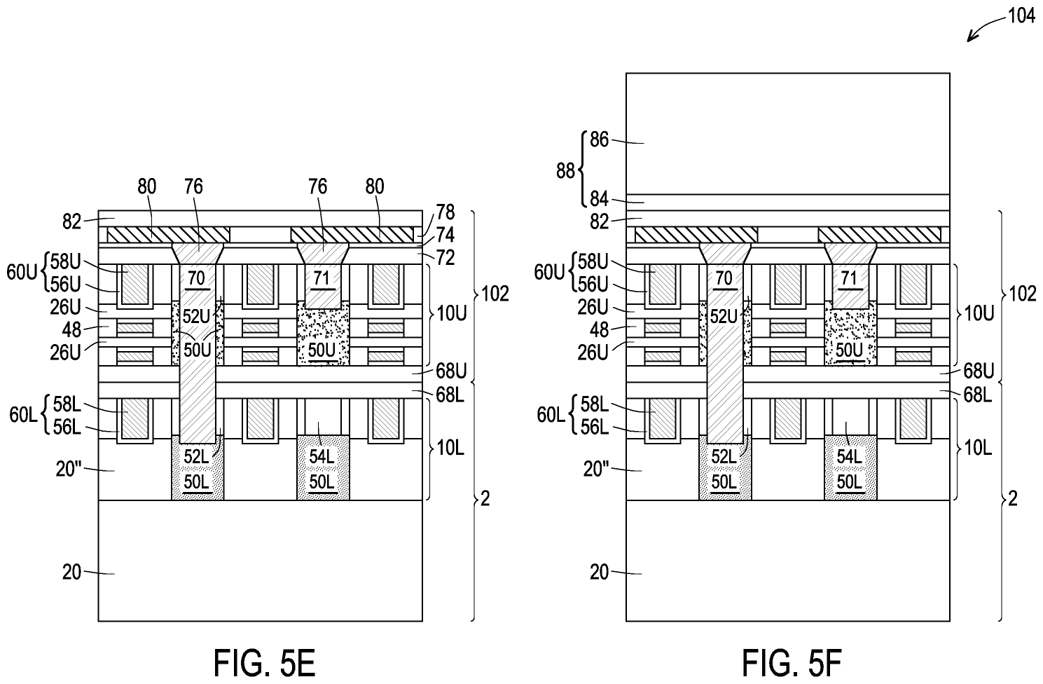

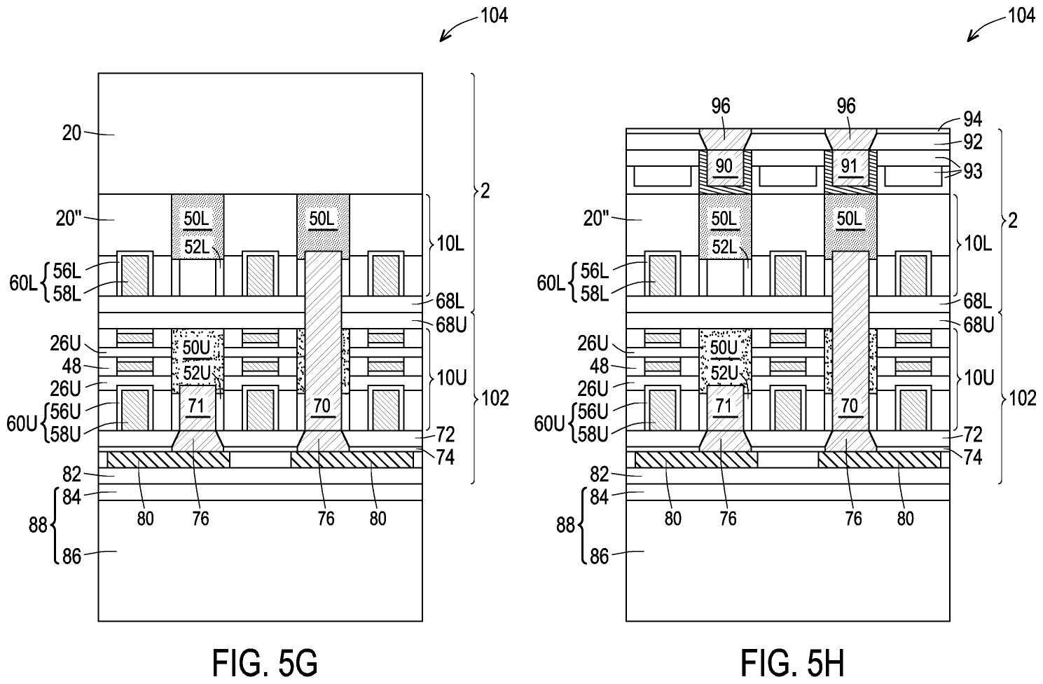

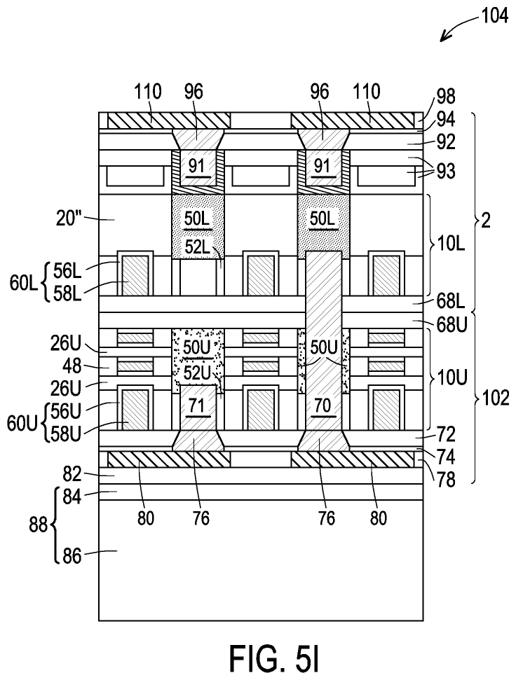

FIGS. 5A-5I illustrate the cross-sectional views of intermediate stages in the formation of CFETs and local interconnects in accordance with alternative embodiments of the present disclosure. The corresponding bonding process is also referred to as a face-to-back process since the front side of the bottom transistors (and the bottom die/wafer) is bonded to the backside of the upper transistors (and the upper die/wafer).

These processes are similar to the processes shown in FIGS. 1A-1N, except that no horizontal metal line is formed between upper transistors and lower transistors for routing electrical signals (and that the lower transistor is illustrated as a FinFET). Alternatively stated, the electrical signals/voltages are routed between the upper transistors and lower transistors vertically, and through deep contact plugs.

FIG. 5A illustrates the formation of transistor 10L in lower wafer 2. In accordance with some embodiments, transistor 10L is a FinFET, which includes source/drain regions 50L, protruding semiconductor fin 20″ that protrudes higher than the bulk portion of substrate 20, and gate electrodes 60 extending on the sidewalls and the top surfaces of protruding semiconductor fin 20″. The protruding semiconductor fin 20″ is further over a bulk semiconductor substrate. In accordance with alternative embodiments, transistors 10L may be a GAA transistor, as shown in FIG. 1E.

Next, as also shown in FIG. 5A, bond layer 68L is formed. Differing from the structure shown in FIG. 1F, in which an inter-metal is formed in lower wafer 2, in the structure shown in FIG. 5A, no horizontal metal line/pad is formed over transistor 10L.

FIG. 5B illustrates the bonding of upper wafer 102 to lower wafer 2. Upper wafer 102 is essentially the same as discussed in preceding embodiments, and the details are not repeated herein. Upper wafer 102 may include semiconductor substrate 120, and alternating semiconductor layers 26U and dummy semiconductor layers 24U. The bonding may be achieved by bonding bond layer 68U to bond layer 68L.

Next, as shown in FIG. 5C, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L. Also, although transistor 10U is illustrated as a GAA transistor in an example, transistor 10U may also be a FinFET in accordance with alternative embodiments.

Next, referring to FIG. 5D, contact plug 71 is formed. Contact plug 71 is electrically connected to one of source/drain regions 50U, and is landed on the top surface of the source/drain region 50U. There may be a silicide region (not shown) between and contacting contact plug 71 and source/drain region 50U.

Deep contact plug 70 is also formed, and penetrates through one of source/drain regions 50U and lands on one of the source/drain regions 50L. Deep contact plug 70 acts as both of the source/drain contact plug and the deep via (the local interconnect) interconnecting source/drain regions 50U and 50L. In accordance with some embodiments, the formation process may include etching ILD 54U (FIG. 5A) and CESL 52U (if having horizontal portions), source/drain regions 50U, bond layers 68U and 68L, ILD 54L, and CESL 52L (if having horizontal portions). The source/drain region 50L is thus exposed to the respective trench. A conductive material(s) is then filled into the resulting trench to form deep contact plug 70. There may be source/drain silicide regions (not shown) formed between deep contact plug 70 and source/drain region 50U, and between deep contact plug 70 and source/drain region 50L.

Referring to FIGS. 5D and 5E, vias 76 and metal lines 80 are also formed, which are in dielectric layers 72, 74, and 78. Bond layer 82 is also formed, and may be planarized.

FIG. 5F illustrates the bonding of carrier 88 to bond layer 82, thus forming composite wafer 104. The resulting composite wafer 104 is then flipped upside down, and the resulting structure is shown in FIG. 5G. Substrate 20 is then removed, for example, in a smart cut process, a CMP process, a mechanical grinding process, and/or an anisotropic etching process. The protruding semiconductor fin 20″ and source/drain regions 50L in the lower transistor 10L are thus exposed.

FIG. 5H illustrates the formation of additional features including source/drain contact plugs 91, and an interconnect structure including via 96 and the corresponding dielectric layers 93, 92, and 94. Although not illustrated, there may be metal silicide regions formed between source/drain contact plugs 91 and source/drain regions 50L. Source/drain contact plugs 91 are thus electrically connected to source/drain regions 50U through source/drain regions 50L and deep contact plug 70. Differing from the embodiments in FIG. 1N, in which both of the source/drain regions 50L and 50U are penetrated-through in order to provide the electrical paths through them, one of source/drain regions 50L is used to provide through-connection.

FIG. 5I illustrates the formation of an interconnect structure including dielectric layers and metal lines, which are represented by dielectric layer 98 and metal lines 110. In subsequent processes, more overlying metal layers and vias may be formed, and the resulting composite wafer 104 may be sawed into dies. In the resulting dies obtained from the singulated composite wafer 104, the deep contact plug 70 acts as a part of the local interconnect for interconnecting source/drain regions 50L and 50U.

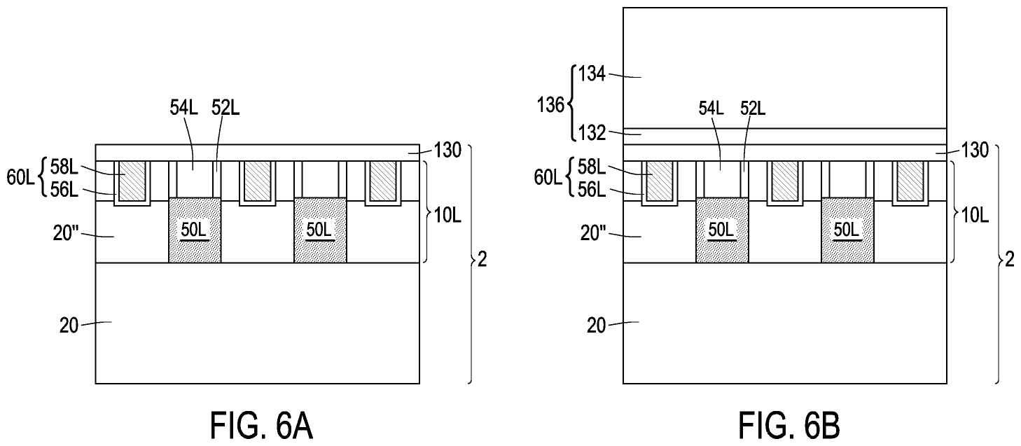

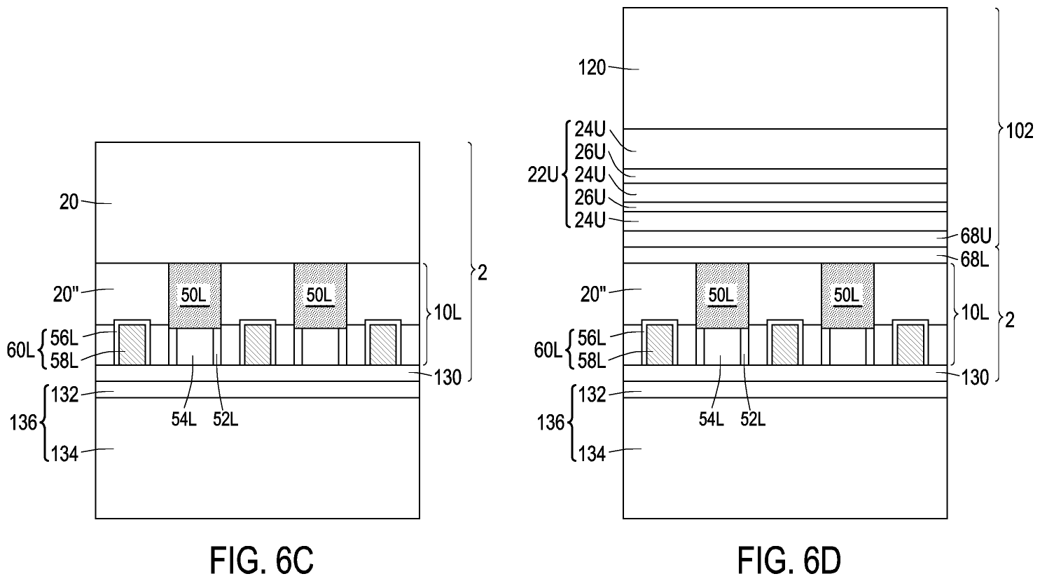

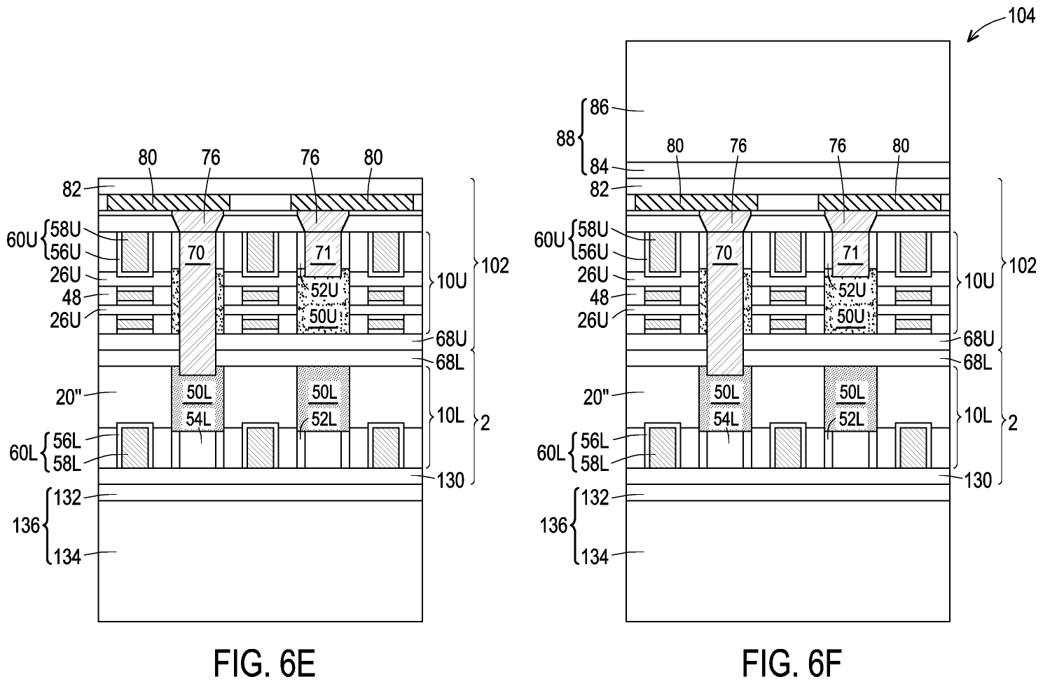

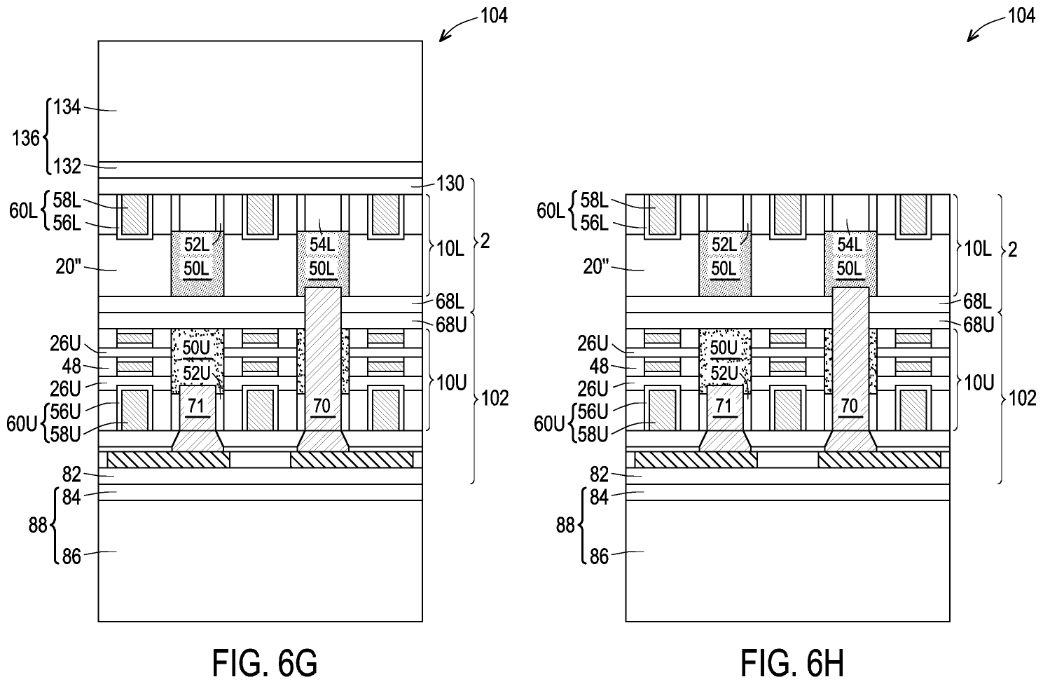

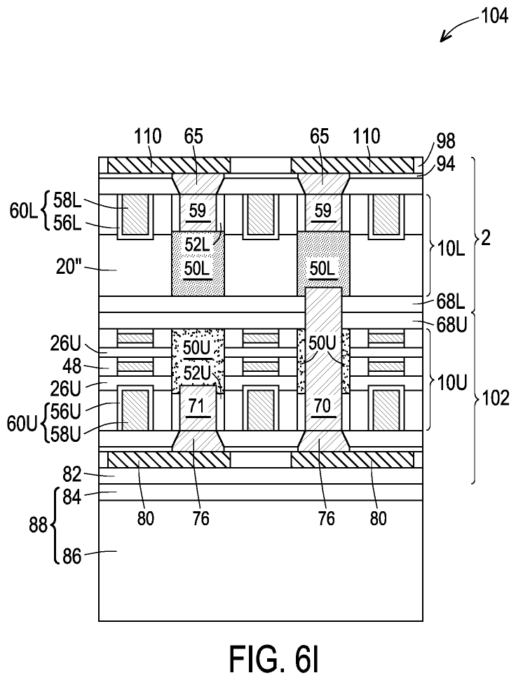

FIGS. 6A-6I illustrate the cross-sectional views of intermediate stages in the formation of CFETs and local interconnects in accordance with alternative embodiments of the present disclosure. The corresponding bonding process is also referred to as a back-to-back process since the backside of the bottom transistors (and the bottom die/wafer) is bonded to the backside of the upper transistors (and the upper die/wafer).

These processes are similar to the processes shown in FIGS. 3A-3J, except that no metal line (inter-metal) is formed between upper transistors and lower transistors. Alternatively stated, no horizontal metal lines are formed between the upper transistors and lower transistors. Rather, the connection of the transistors and lower transistors are through deep contact plugs. Furthermore, in accordance with these embodiments, lower transistor 10L may be a FinFET as shown in FIG. 6A, or may be a GAA transistor.

FIG. 6A illustrates the formation of transistor 10L in lower wafer 2. In accordance with some embodiments, transistor 10L is a FinFET, which includes source/drain regions 50L, protruding semiconductor fin 20″ that protrudes higher than the bulk portion of substrate 20, and gate electrodes 60 extending on the sidewalls and the top surfaces of protruding semiconductor fin 20″. The protruding semiconductor fin 20″ is further over a bulk semiconductor substrate.

Next, as also shown in FIG. 6A, bond layer 130 is formed. Differing from the structure shown in FIG. 3E, in which a metal line (an inter-metal) is formed in lower wafer 2, in the lower wafer 2 as shown in FIG. 6A, no horizontal metal line is formed over transistor 10L.

FIG. 6B illustrates the bonding of carrier 136 to bond layer 130. In accordance with some embodiments, carrier 136 includes semiconductor substrate 134, which may be a silicon substrate. Bond layer 132 is formed on semiconductor substrate 134. The bonding of bond layer 132 to bond layer 130 may be through fusion bonding in accordance with some embodiments. In accordance with alternative embodiments, carrier 136 includes a transparent substrate (also denoted using reference numeral 134) such as a glass carrier, which is attached to lower wafer 2 through an adhesive such as an LTHC material (also denoted using reference numeral 132).

The structure including lower wafer 2 and carrier 136 is then flipped upside down, and the resulting structure is shown in FIG. 6C. Substrate 20 is then removed, for example, in a smart cut process, a CMP process, a mechanical grinding process, and/or an anisotropic etching process. The protruding semiconductor fin 20″ and source/drain regions 50L in the lower transistor 10L are thus exposed. A bond layer 68L (FIG. 6D) is then formed as a top surface layer of wafer 2.

Further referring to FIG. 6D, wafer 102 is bonded to wafer 2 through fusion bonding. Wafer 102 may be essentially the same as discussed in preceding embodiments, and the details are not repeated herein.

Next, as shown in FIG. 6E, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L.

Next, further referring to FIG. 6E, contact plug 71 is formed. Contact plug 71 is electrically connected to one of source/drain regions 50U, and is landed on the top surface of the source/drain region 50U. There may be a silicide region (not shown) between and contacting contact plug 71 and source/drain region 50U.

Deep contact plug 70 is also formed, and penetrates through one of source/drain region 50U, and lands on the source/drain region 50L. Deep contact plug 70 acts as both of the source/drain contact plug and the deep via (local interconnect) interconnecting source/drain regions 50U and 50L. There may be source/drain silicide regions (not shown) formed between deep contact plug 70 and source/drain region 50U, and between deep contact plug 70 and source/drain region 50L.

FIG. 6E also illustrates the formation of vias 76 and metal lines 80, which are formed in dielectric layers 72, 74, and 78. Bond layer 82 is also formed, and may be planarized.

FIG. 6F illustrates the bonding of carrier 88 to bond layer 82, thus forming composite wafer 104. The resulting composite wafer 104 is then flipped upside down, and the resulting structure is shown in FIG. 6G.

Carrier 136 is then removed, and the resulting structure is shown in FIG. 6H. In accordance with some embodiments in which carrier 136 is bonded to bond layer 130 through fusion bonding, the removal of carrier 136 may include a smart cut process, a CMP process, a mechanical grinding process, and/or an anisotropic etching process. Otherwise, a laser beam may be used to de-bond carrier 136 from the underlying structure. Bond layer 130 is also removed, and lower transistor 10L is thus exposed.

FIG. 6I illustrates the formation of additional features including source/drain contact plugs 59, and an interconnect structure including via 65 and the corresponding dielectric layers. The interconnect structure may also include metal lines 110. Although not illustrated, there may be metal silicide regions formed between source/drain contact plugs 59 and source/drain regions 50L. A source/drain contact plug 59 is thus electrically connected to one of source/drain regions 50U through a corresponding source/drain region 50L, and through deep contact plug 70. Differing from the embodiments in FIG. 1N, in which both of the source/drain regions 50L and 50U are penetrated-through in order to provide the electrical paths through them, one of source/drain regions 50L (illustrated on the right side of FIG. 6I) is used to provide through-connection.

In subsequent processes, more layers/features may be formed, and the resulting composite wafer 104 may be sawed into dies. In the resulting dies obtained from the singulated composite wafer 104, the deep contact plug 70 acts as a part of the local interconnect for interconnecting source/drain regions 50L and 50U.

In the embodiments formed through sequential formation processes, the upper transistor is formed based on the semiconductor materials of an upper wafer, and the formation of the upper transistor is performed after the upper wafer is bonded to the lower wafer. Since the selection of the structure and the material of the upper wafer has flexibility, the semiconductor materials for forming the channels of the upper transistors and the lower transistors may be selected separately based on the conductivity types of the respective transistors, and may have different surface orientations. For example, the surface orientation of the p-type transistors may be selected as being (110), while the surface orientation of the n-type transistors may be selected as being (100), so that the performance of both of the upper transistors and the lower transistors are optimized. Also, the upper transistors and the lower transistors may have different numbers of semiconductor nanostructures. In addition, it is possible to form the upper transistors and lower transistors as different types of transistors (such as GAA transistors and FinFETs).

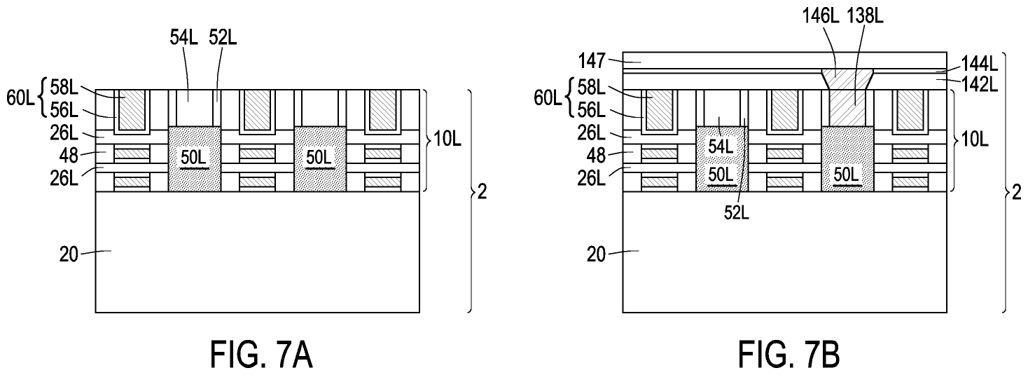

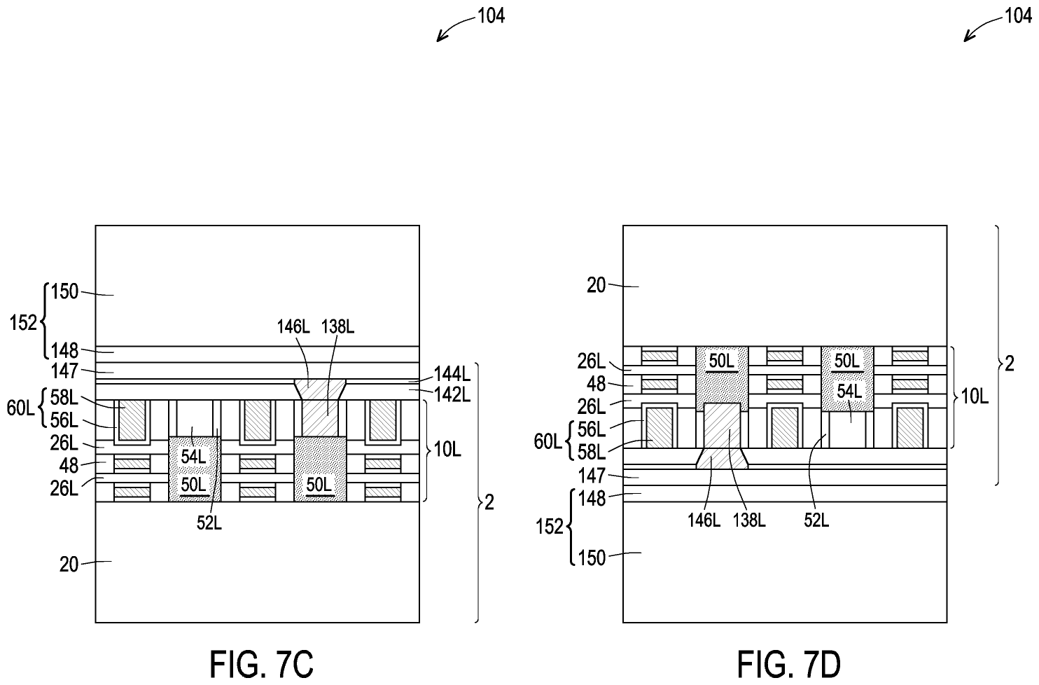

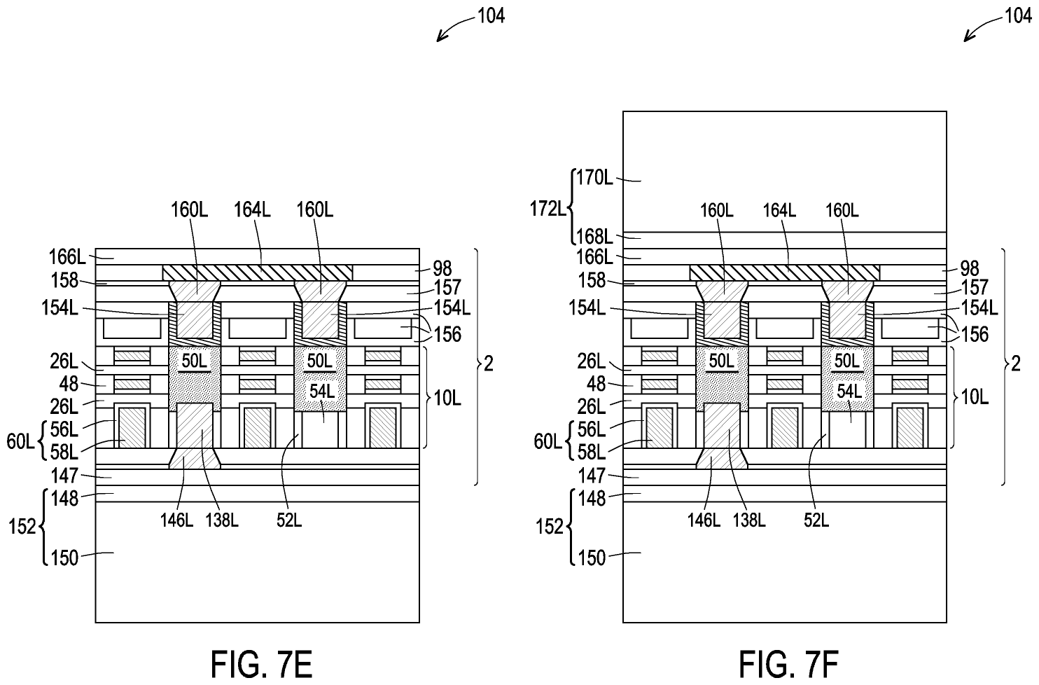

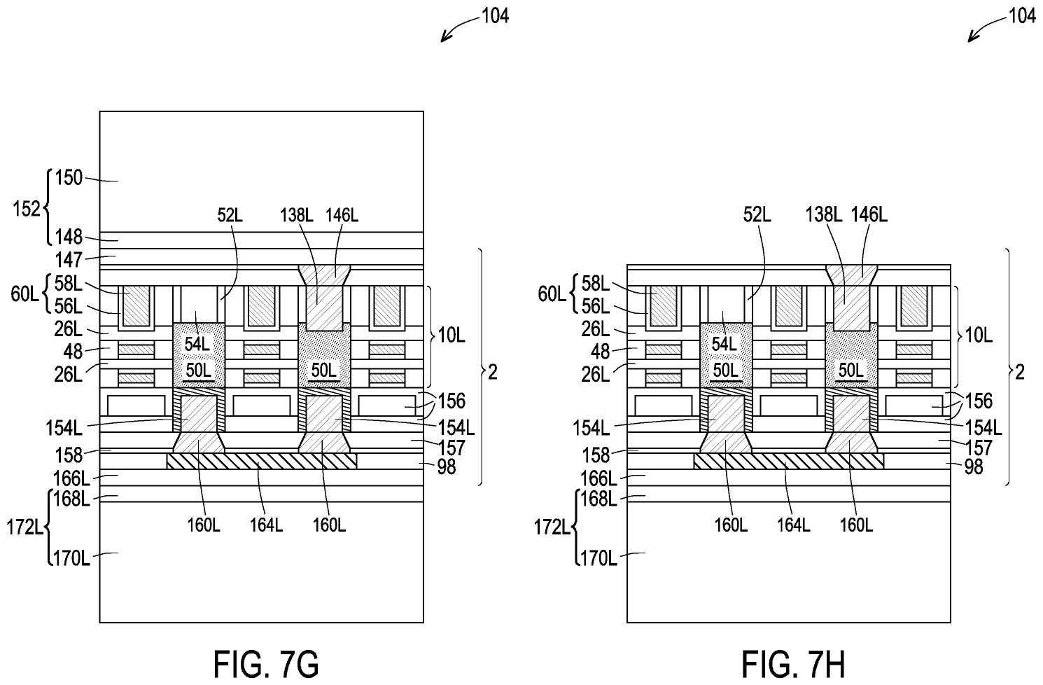

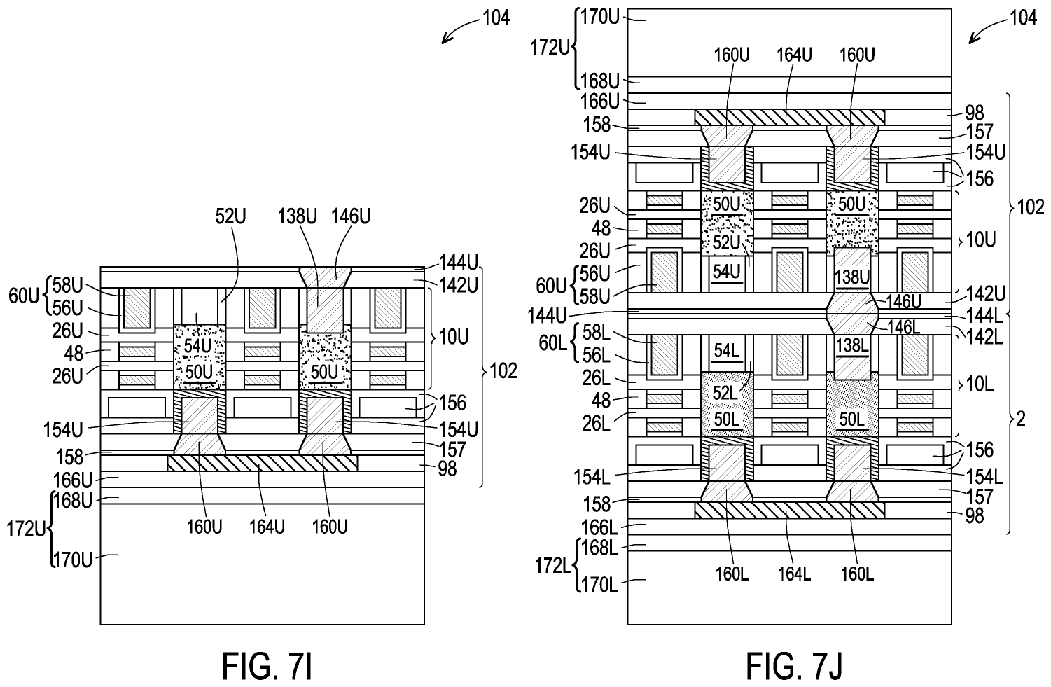

FIGS. 7A-7J, 8A-8G, 9A-9J, 10A-10E, 11A-11E, and 12A-12C illustrate the views of the formation of CFETs through parallel formation processes in accordance with some embodiments. In the parallel formation processes, upper transistors and lower transistors are formed separately in an upper wafer and a lower wafer. Accordingly, although some features in these processes are marked using letter “L” to indicate they are lower features, and some features in these processes are marked using letter “U” to indicate they are upper features, the concept of “lower” and “upper” in the parallel formation processes are merely for the convenience of discussion.

The upper wafer and the lower wafer that are formed in parallel processes are then bonded together, and local interconnects are formed to interconnect the upper transistors and the lower transistors. Unless specified otherwise, the materials, the structures, and the formation processes of the components in these embodiments are essentially the same as the like components denoted by like reference numerals in the sequential formation processes. The details regarding the materials, the structures, and the formation processes provided in any of the embodiments throughout the description may also be applied to any other embodiment whenever applicable.

FIGS. 7A-7J illustrate the cross-sectional views of intermediate stages in the formation of CFETs and local interconnects in accordance with alternative embodiments of the present disclosure. The corresponding bonding process is also referred to as a face-to-face process since the front side of the bottom transistors (and the bottom die/wafer) is bonded to the front side of the upper transistors (and the upper die/wafer). Since the front sides of the wafers are bonded to each other, the interconnect structure in each of the lower wafer and the upper wafer are formed on the backside of the respective wafers. Furthermore, in these processes, there is no horizontal metal lines formed between the lower transistors and the upper transistors for electrically routing electrical signals/currents/voltages laterally. Rather, electrical connection between upper transistors and lower transistors are routed vertically.

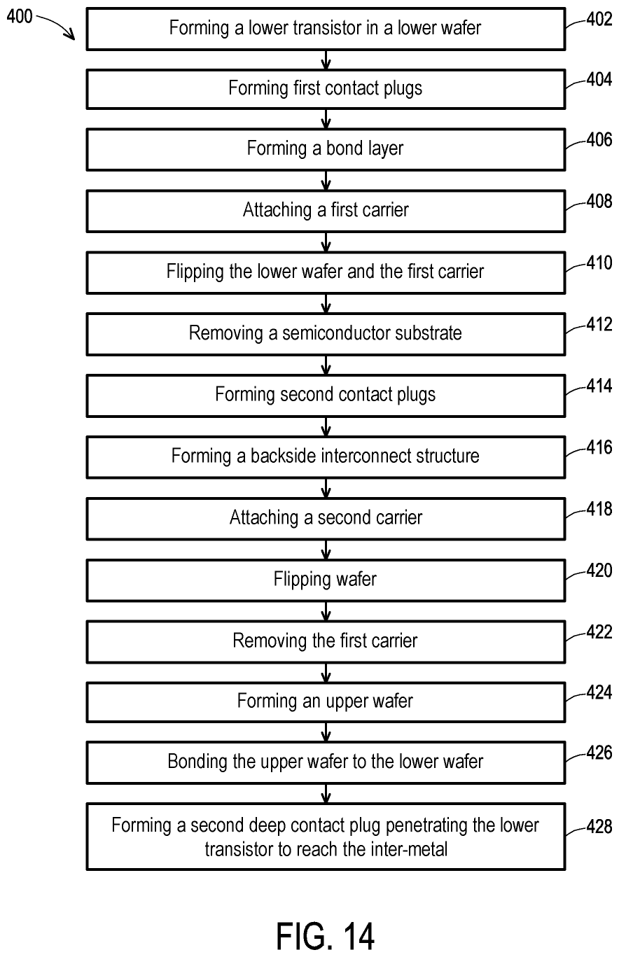

FIG. 7A illustrates the formation of transistor 10L in lower wafer 2 in accordance with some embodiments. The respective process is also illustrated as process 402 in the process flow 400 as shown in FIG. 14. The formation processes are essentially the same as what is illustrated in FIGS. 1A through 1E, and the details are not repeated herein. In accordance with some embodiments, transistor 10L includes semiconductor nanostructures 26L forming the channels, source/drain regions 50L, and gate stacks 60L wrapping around the semiconductor nanostructures 26L.

Referring to FIG. 7B, contact plugs 138L are formed. The respective process is also illustrated as process 404 in the process flow 400 as shown in FIG. 14. In accordance with some embodiments, the formation process may include etching the respective CESL 52L and ILD 54L (FIG. 7A) to form contact openings and to reveal source/drain regions 50L, forming silicide regions on the exposed source/drain regions 50L, and forming contact plugs 138L in the contact openings. Contact plugs 138L may be formed through a damascene process, and may include tungsten, cobalt, nickel, or the like. Contact plugs 138L may also comprise a diffusion barrier formed of, for example, Ti, TiN, Ta, TaN, or the like.

Dielectric layers 142L and 144L are formed over contact plug 138L and gate stacks 60L. There may be, or may not be, an etch stop layer under dielectric layer 142L and over source/drain regions 50L and gate stacks 60L. In accordance with some embodiments, dielectric layer 142L comprises a dielectric material such as silicon oxide, silicon nitride, silicon oxynitride, silicon carbide, PSG, BSG, BPSG, USG, or the like Dielectric layer 142L may also be a low-k dielectric material, which may be a silicon-and-carbon containing dielectric material. Dielectric layer 144L may (or may not) act as an etch stop layer, and may be formed of or comprise AlN, AlO, SiOC, and/or the like, combinations thereof, and/or multi-layers thereof. Bond pad 146L is formed in dielectric layer 142L, and may (or may not) penetrate through dielectric layer 144L.

Further referring to FIG. 7B, bond layer 147 is formed. The respective process is also illustrated as process 406 in the process flow 400 as shown in FIG. 14. In accordance with some embodiments, bond layer 147 is formed of or comprises a silicon-containing dielectric material such as SiO, SiN, SiN, SION, SiCN, SiOCN, or the like, combinations thereof, and/or multi-layers thereof. In accordance with alternative embodiments, bond layer 147 is formed of a polymer such as polyimide or PBO.

Carrier layer 152 is then attached over wafer 2. The respective process is also illustrated as process 408 in the process flow 400 as shown in FIG. 14. In accordance with some embodiments, carrier 152 includes semiconductor substrate 150, which may be a silicon substrate. Bond layer 148 is formed on semiconductor substrate 150. Bond layer 148 may be formed through a deposition process or a thermal oxidation process, and may be formed of a material that is selected from the same group of candidate materials of bond layer 147. The bonding of bond layer 148 to bond layer 147 may be through fusion bonding in accordance with some embodiments.

In accordance with alternative embodiments, carrier 152 includes a transparent substrate (also denoted using reference numeral 150) such as a glass substrate, which is attached to wafer 2 through an adhesive such as an LTHC material (also denoted using reference numeral 148). The structure including lower wafer 2 and carrier 152 is then flipped upside down, and the resulting structure is shown in FIG. 7D. The respective process is also illustrated as process 410 in the process flow 400 as shown in FIG. 14.

Next, the substrate 20 as shown in FIG. 7D is removed. The respective process is also illustrated as process 412 in the process flow 400 as shown in FIG. 14. The removal of substrate 20 may include, for example, a smart cut process, a CMP process, a mechanical grinding process, and/or an anisotropic etching process. As a result, the gate stack 60L and the source/drain regions 50L as shown in FIG. 7D are exposed. The resulting structure is shown as a lower part of the structure in FIG. 7E.

FIG. 7E further illustrates the formation of contact plugs and an overlying backside interconnect structure. In accordance with some embodiments, contact plugs 154L are formed over and electrically connecting to source/drain regions 50L. The respective process is also illustrated as process 414 in the process flow 400 as shown in FIG. 14. Although not illustrated, there may be metal silicide regions formed between source/drain regions 50L and contact plugs 154L. Contact plugs 154L are formed in dielectric layers 156, which may include a plurality of layers formed of different dielectric materials.

FIG. 7E further illustrates the formation of a backside interconnect structure comprising vias 160L, metal lines 164L, and a plurality of dielectric layers. The respective process is also illustrated as process 416 in the process flow 400 as shown in FIG. 14. The dielectric layers include dielectric layers 157 and 158. In accordance with some embodiments, dielectric layers 156 and 157 may comprise low-k dielectric materials, which may be silicon-and-carbon containing dielectric materials. Dielectric layer 158 may (or may not) act as an etch stop layer, and may be formed of or comprise AlN, AlO, SiOC, and/or the like, combinations thereof, and/or multi-layers thereof. Vias 160L are formed in dielectric layer 157, and may (or may not) penetrate through dielectric layer 158.

Metal lines 164L may be formed through a damascene process, and may include copper, tungsten, nickel, or the like. Each of metal lines 164L may also comprise a diffusion barrier. It is appreciated that although one metal layer is illustrated, the illustrated metal layer represents a plurality of metal layers, which collectively form the backside interconnect structure of wafer 2.

Bond layer 166L is then formed over the backside interconnect structure. In accordance with some embodiments, bond layer 166L is deposited, and may be formed of or comprise a silicon-containing dielectric material such as SiO, SiN, SiN, SiON, SiCN, SiOCN, or the like, combinations thereof, and/or multi-layers thereof. Bond layer 166L may be planarized in a CMP process or a mechanical polishing process to planarize its top surface. In accordance with alternative embodiments, bond layer 166L is formed of a polymer such as polyimide or PBO.

Referring to FIG. 7F, carrier 172L is attached to wafer 2. The respective process is also illustrated as process 418 in the process flow 400 as shown in FIG. 14. In accordance with some embodiments, carrier 172L includes semiconductor substrate 170L, which may be a silicon substrate in accordance with some embodiments. Bond layer 168L is formed on semiconductor substrate 170L. Bond layer 168L may be formed through a deposition process or a thermal oxidation process, and may be formed of a material that is selected from the same group of candidate materials of bond layer 166L. The bonding of bond layer 168L to bond layer 166L may be through fusion bonding in accordance with some embodiments.

In accordance with alternative embodiments, carrier 172L includes a transparent substrate (also denoted using reference notation 170L) such as a glass substrate, which is attached to lower wafer 2 through an adhesive (also denoted using reference notation 168L) such as an LTHC material.

The structure shown in FIG. 7F is then flipped upside down, and the resulting structure is shown in FIG. 7G. The respective process is also illustrated as process 420 in the process flow 400 as shown in FIG. 14.

Next, the carrier 152 shown in FIG. 7G is removed. The respective process is also illustrated as process 422 in the process flow 400 as shown in FIG. 14. When carrier 152 includes a semiconductor substrate and a bond layer, carrier 152 may be removed in a smart cut process, a CMP process, a mechanical grinding process, and/or an anisotropic etching process. Alternatively, when carrier 152 includes a glass substrate and an LTHC material, the removal process includes a de-bonding process, in which a laser beam is used to decompose the LTHC material, so that the glass substrate may be detached from wafer 2. As a result, the front side of gate stack 60L and the source/drain regions 50L as shown in FIG. 7G are exposed. After the removal of carrier 152, the bond layer 148 and 147 may also be removed, for example, in a polishing process or an etching process.

FIG. 7I illustrates the formation of transistors 10U in upper wafer 102. The respective process is also illustrated as process 424 in the process flow 400 as shown in FIG. 14. The formation processes may also be essentially the same as what is illustrated in FIGS. 7A through 7H, and the details are not repeated herein. In accordance with some embodiments, transistor 10U includes semiconductor nanostructures 26U forming the channels, source/drain regions 50U, and gate stacks 60U wrapping around the semiconductor nanostructures 26U.

Under transistors 10U, an interconnect structure including contact plugs 154U, vias 160U, and metal lines 164U are formed, and are connected to transistors 10U. Over transistors 10U, contact plugs 138U and bond pads 146U are also formed. Bond pads 146U are in the bond layer 144U and the underlying dielectric layer 142U. Wafer 102 may include carrier 172U for supporting transistor 10U, which may have the structure selected from the candidate structures and materials of carrier 172L (FIG. 7H).

Next, referring to FIG. 7J, wafer 2 is bonded to wafer 102. The respective process is also illustrated as process 426 in the process flow 400 as shown in FIG. 14. The bonding process may include hybrid bonding, which includes the bonding of bond pads 146L and 146U through metal-to-metal direct bonding, and the bonding of bond layers 144L and 144U through fusion bonding. Accordingly, a source/drain region 50L is electrically connected to a source/drain region 50U through bond pads 146L and 146U and contact plugs 138L and 138U. Furthermore, a metal line 164L is connected to a metal line 164U through contact plugs 138L and 138U and bond pads 146L and 146U, and further through.

In subsequent processes, either one or both of carriers 172L and 172U may be removed, and more layers/features may be formed. The resulting composite wafer 104 may be sawed into dies. In the resulting dies obtained from the singulated composite wafer 104, the bonded bond pads act as parts of the local interconnect for interconnecting source/drain regions 50L and 50U.

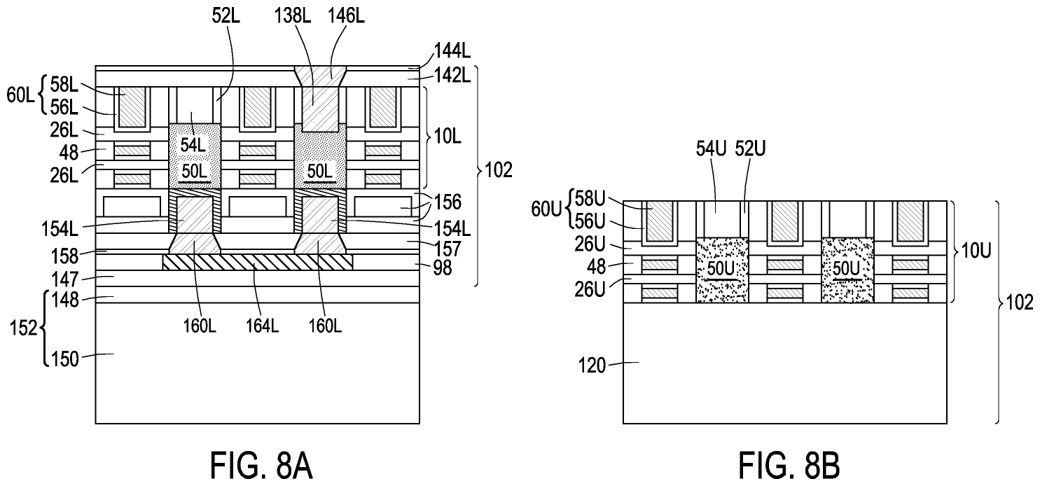

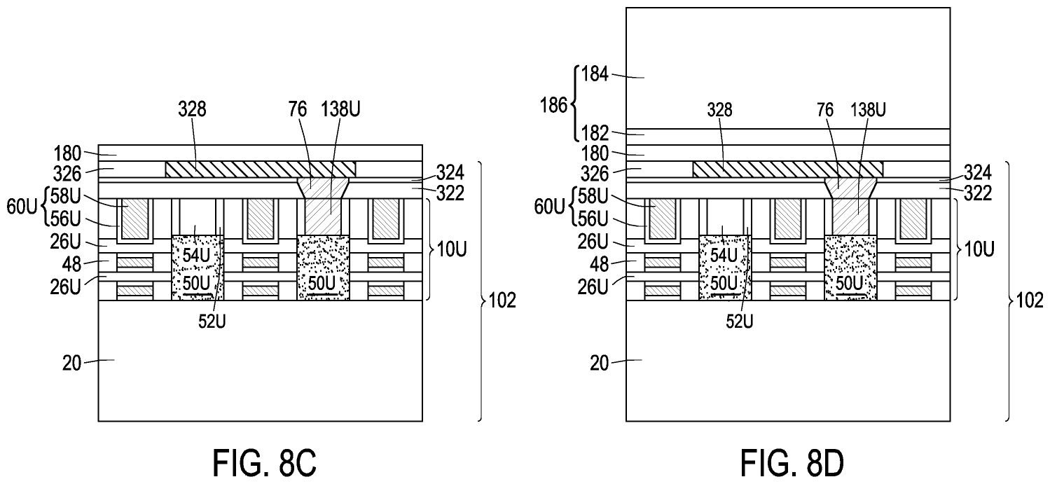

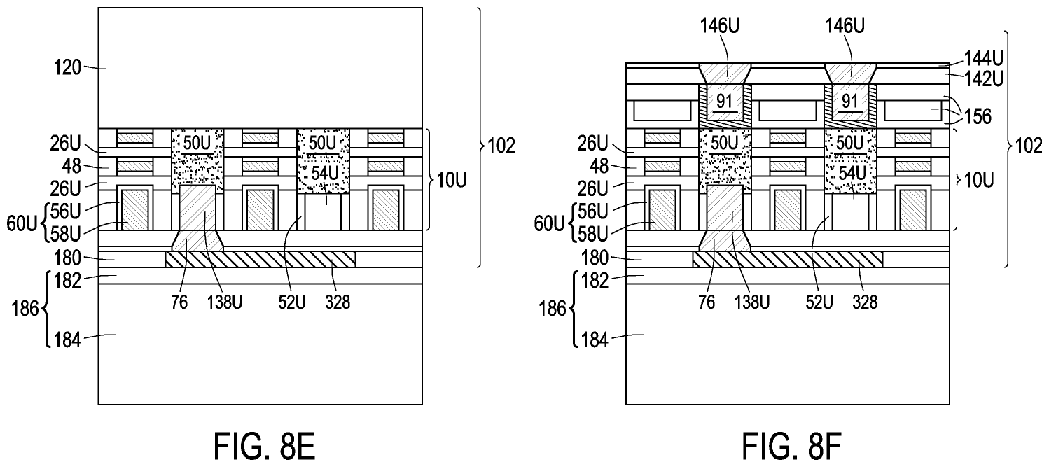

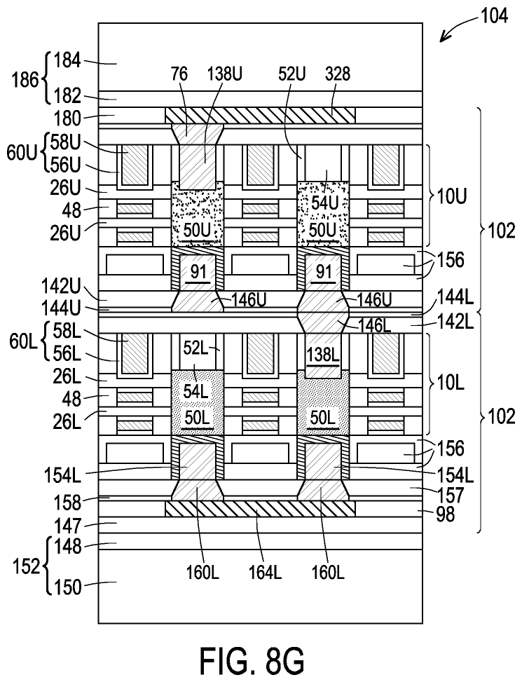

FIGS. 8A-8G illustrate the cross-sectional views of intermediate stages in the formation of CFETs and local interconnects in accordance with alternative embodiments of the present disclosure. The corresponding bonding process is also referred to as a face-to-back process since the front side of the bottom transistors (and the bottom die/wafer) is bonded to the backside of the upper transistors (and the upper die/wafer). Since the front side of the lower wafer is bonded to the upper wafer, the interconnect structure in the lower wafer will be formed on the backside of the lower wafer. The interconnect structure in the upper wafer, on the other hand, will be formed on its front side.

FIG. 8A illustrates the formation of transistor 10L in lower wafer 2 in accordance with some embodiments. The structure shown in FIG. 8A may be formed using essentially the same processes as shown in FIGS. 7A through 7E. The details are thus not repeated herein. In accordance with some embodiments, transistor 10L includes semiconductor nanostructures 26L forming the channels, source/drain regions 50L, and gate stacks 60L wrapping around the semiconductor nanostructures 26L. Bond pad 146L and bond layer 144L are formed on the top surface of lower wafer 2. In accordance with these embodiments, no bond layer is formed on the top surface of lower wafer 2 since the bond pad 146L will be bonded to the upper wafer directly.

FIGS. 8B through 8F illustrate the formation of upper wafer 102 in accordance with some embodiments. Referring to FIG. 8B, transistors 10U are formed in upper wafer 102. The formation processes may also be essentially the same as what is illustrated in FIGS. 1A through 1E, and the details are not repeated herein. In accordance with some embodiments, transistors 10U include semiconductor nanostructures 26U forming the channels, source/drain regions 50U, and gate stacks 60U wrapping around the semiconductor nanostructures 26U.

FIG. 8C illustrates the formation of contact plugs and an overlying interconnect structure. In accordance with some embodiments, contact plugs 138U are formed over and electrically connecting to source/drain regions 50U. Contact plugs 138U are formed in the respective CESL 52U and ILD 54U (FIG. 8B). Contact plugs 138U may be formed of a conductive material, which may be a metallic material such as tungsten, cobalt, copper, Ti, TiN, Ta, TaN, or the like, combinations thereof, and/or multi-layers thereof. Although not illustrated, source/drain silicide layers may be formed between, and contacting, upper source/drain region 50U and contact plugs 138U.

Over contact plugs 138U, an interconnect structure is formed. The interconnect structure may include dielectric layers 322 and 324, and via 76 in dielectric layers 322 and 324. Another etch stop layer (not shown) may also be formed underlying and contacting dielectric layer 322, if needed. In accordance with some embodiments, dielectric layer 322 comprises a low-k dielectric material, which may be a silicon-and-carbon containing dielectric material. Dielectric layer 324 may (or may not) act as an etch stop layer, and may be formed of or comprise AlN, AlO, SiOC, and/or the like, combinations thereof, and/or multi-layers thereof. Via 76 is formed in dielectric layer 322, and may (or may not) penetrate through dielectric layer 324.

The interconnect structure further includes dielectric layer 326 and metal lines 328. Dielectric layer 326 may also be formed of a low-k dielectric material or a non-low-k dielectric material such as silicon oxide, silicon nitride, silicon carbide, or the like, or combinations thereof. Metal lines 328 may be formed through a damascene process, and may include copper, tungsten, nickel, or the like. Each of metal lines 328 may also comprise a diffusion barrier. It is appreciated that although one metal layer is illustrated, the illustrated metal layer represents a plurality of metal layers, which collectively form the front-side interconnect structure of wafer 102.

Bond layer 180 is then formed over the interconnect structure. In accordance with some embodiments, bond layer 180 is deposited, and may be formed of or comprise a silicon-containing dielectric material such as SiO, SiN, SiN, SION, SiCN, SiOCN, or the like, combinations thereof, and/or multi-layers thereof. Bond layer 180 may be planarized in a CMP process or a mechanical polishing process to planarize its top surface. In accordance with alternative embodiments, bond layer 180 is formed of a polymer such as polyimide or PBO.

Referring to FIG. 8D, carrier 186 is attached to wafer 102. In accordance with some embodiments, carrier 186 includes semiconductor substrate 184, which may be a silicon substrate in accordance with some embodiments. Bond layer 182 is formed on semiconductor substrate 184. Bond layer 182 may be formed through a deposition process or a thermal oxidation process, and may be formed of a material that is selected from the same group of candidate materials of bond layer 180. The bonding of bond layer 182 to bond layer 180 may be through fusion bonding in accordance with some embodiments.

In accordance with alternative embodiments, carrier 186 includes a transparent substrate (also denoted using reference numeral 184) such as a glass substrate, which is attached to lower wafer 2 through an adhesive (also denoted using reference numeral 182) such as an LTHC material. The structure shown in FIG. 8D is then flipped upside down, and the resulting structure is shown in FIG. 8E.

Next, substrate 120 is removed, for example, through a smart cut process (to remove a majority portion of substrate 120), a CMP process, a mechanical grinding process, and/or an anisotropic etching process. After the removal, transistor 10U is exposed.

Referring to FIG. 8F, contact plugs 91 are formed in the respective opening. Contact plug 91 may be formed of a conductive material, which may be a metallic material such as tungsten, cobalt, copper, Ti, TiN, Ta, TaN, or the like, combinations thereof, and/or multi-layers thereof. Although not illustrated, source/drain silicide layers may be formed between, and contacting upper source/drain region 50U and contact plug 91. Contact plugs 91 may be formed through a damascene process, and may include tungsten, cobalt, nickel, or the like. Each of contact plugs 91 may also comprise a diffusion barrier formed of, for example, Ti, TiN, Ta, TaN, or the like.

Bond pad 146U and bond layer 144U are formed on the top surface of lower wafer 2. In accordance with these embodiments, no bond layer is formed on the top surface of lower wafer 2 since the bond pad 146U will be bonded to the lower wafer directly.

Referring to FIG. 8G, wafer 102 is bonded to wafer 2. The bonding process may include hybrid bonding, which includes the bonding of bond pads 146L and 146U through metal-to-metal direct bonding, and the bonding of bond layers 144L and 144U through fusion bonding. Accordingly, source/drain regions 50L and source/drain regions 50U are interconnected through contact plugs 138L and 91 and bond pads 146L and 146U. Furthermore, metal lines 164L and 328 are interconnected through the conductive features in between.

In subsequent processes, either one or both of carriers 152 and 186 may be removed, and more layers/features may be formed, and the resulting composite wafer 104 may be sawed into dies. In the resulting dies obtained from the singulated composite wafer 104, the bonded bond pads 146L and 146U act as parts of the local interconnect for interconnecting source/drain regions 50L and 50U.

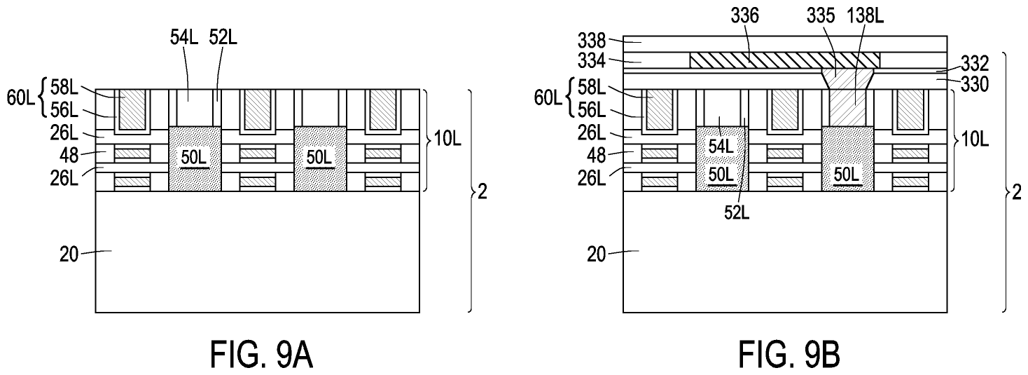

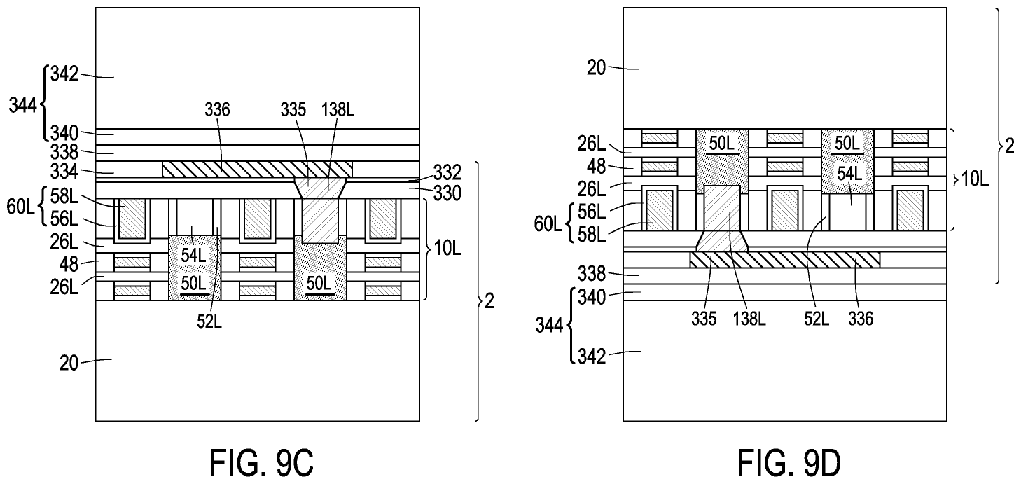

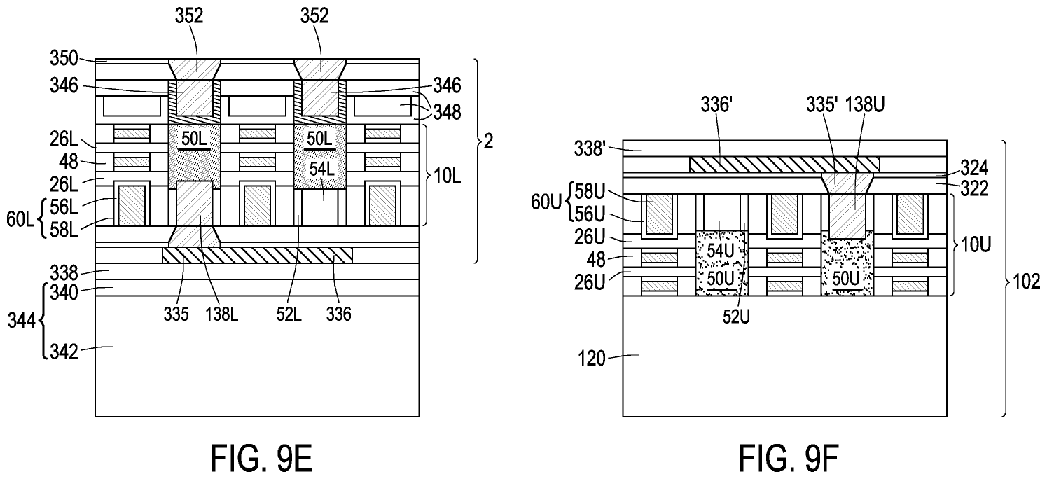

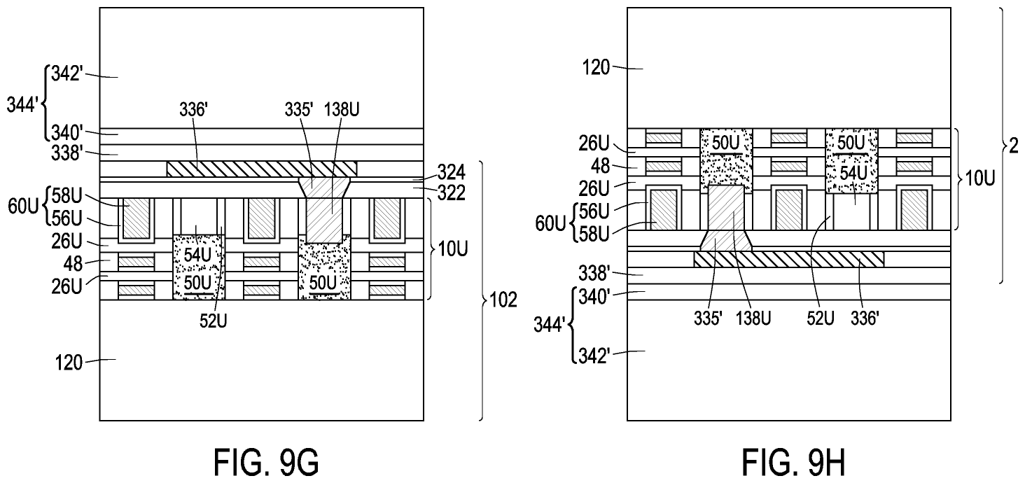

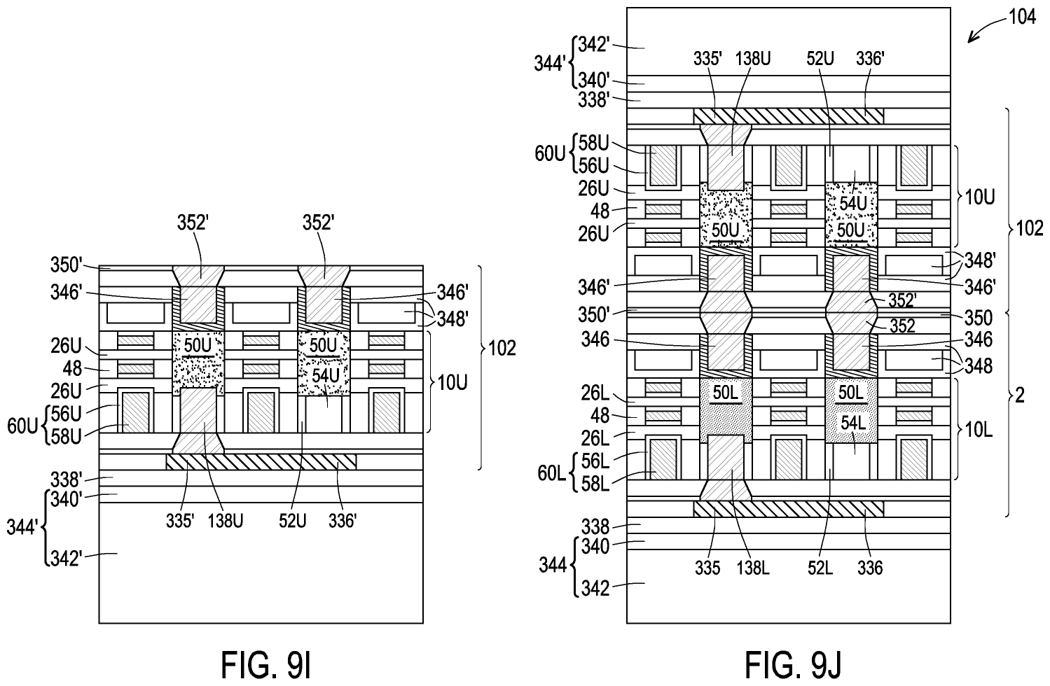

FIGS. 9A-9J illustrate the cross-sectional views of intermediate stages in the formation of CFETs and local interconnects in accordance with alternative embodiments of the present disclosure. The corresponding bonding process is also referred to as a back-to-back process since the backside of the bottom transistors (and the bottom die/wafer) is bonded to the backside of the upper transistors (and the upper die/wafer). Since the backsides of the lower wafer is bonded to the backside of the upper wafer, the interconnect structures in the lower wafer and the upper wafer will be formed on the front sides of the respective wafers.

FIGS. 9A through 9E illustrate the formation of lower wafer 2 in accordance with some embodiments. Referring to FIG. 9A, transistors 10L are formed in lower wafer 2. The formation processes may also be essentially the same as what is illustrated in FIGS. 1A through 1E, and the details are not repeated herein. In accordance with some embodiments, transistors 10L include semiconductor nanostructures 26L forming the channels, source/drain regions 50L, and gate stacks 60L wrapping around the semiconductor nanostructures 26L.

FIG. 9B illustrates the formation of contact plugs 138L and an overlying interconnect structure. In accordance with some embodiments, contact plugs 138L are formed over and electrically connecting to source/drain regions 50L. Although not illustrated, there may be metal silicide regions formed between source/drain regions 50L and contact plugs 138L. Contact plugs 138L are formed in the respective CESL 52L and ILD 54L (FIG. 9A). Contact plugs 138L may be formed of a conductive material, which may be a metallic material such as tungsten, cobalt, copper, Ti, TiN, Ta, TaN, or the like, combinations thereof, and/or multi-layers thereof.

Over contact plugs 138L, an interconnect structure is formed. The interconnect structure may include dielectric layers 330 and 332, in which via 335 is formed. Another etch stop layer (not shown) may also be formed between dielectric layer 330 and gate stacks 60L. In accordance with some embodiments, dielectric layer 330 comprises a low-k dielectric material, which may be a silicon-and-carbon containing dielectric material. Dielectric layer 332 may (or may not) act as an etch stop layer, and may be formed of or comprise AlN, AlO, SiOC, and/or the like, combinations thereof, and/or multi-layers thereof. Via 335 is formed in dielectric layer 322, and may (or may not) penetrate through dielectric layer 324.

The interconnect structure further includes dielectric layer 334 and metal lines 336. Dielectric layer 334 may also be formed of a low-k dielectric material or a non-low-k dielectric material such as silicon oxide, silicon nitride, silicon carbide, or the like, or combinations thereof. Metal lines 336 may be formed through a damascene process, and may include copper, tungsten, nickel, or the like. Each of metal lines 336 may also comprise a diffusion barrier. It is appreciated that although one metal layer is illustrated, the illustrated metal layer represents a plurality of metal layers, which collectively form the front-side interconnect structure of wafer 102.

Bond layer 338 is then formed over the front-side interconnect structure. In accordance with some embodiments, bond layer 338 is deposited, and may be formed of or comprise a silicon-containing dielectric material such as SiO, SiN, SiN, SiON, SiCN, SiOCN, or the like, combinations thereof, and/or multi-layers thereof. Bond layer 338 may be planarized in a CMP process or a mechanical polishing process to planarize its top surface. In accordance with alternative embodiments, bond layer 338 is formed of a polymer such as polyimide or PBO.

Referring to FIG. 9C, carrier 344 is attached to wafer 2. In accordance with some embodiments, carrier 344 includes semiconductor substrate 342, which may be a silicon substrate in accordance with some embodiments. Bond layer 340 is formed on semiconductor substrate 342. Bond layer 340 may be formed through a deposition process or a thermal oxidation process, and may be formed of a material that is selected from the same group of candidate materials of bond layer 338. The bonding of bond layer 338 to bond layer 340 may be through fusion bonding in accordance with some embodiments.

In accordance with alternative embodiments, carrier 344 includes a transparent substrate (also denoted using reference numeral 342) such as a glass substrate, which is attached to lower wafer 2 through an adhesive (also denoted using reference numeral 340) such as an LTHC material. The structure shown in FIG. 9C is then flipped upside down, and the resulting structure is shown in FIG. 9D.

Next, substrate 20 is removed or de-bonded. The removal process may include a smart cut process, a CMP process, a mechanical grinding process, and/or an anisotropic etching process. After the removal of substrate 20, the bond layers 338 and 340 are also removed, for example, in a polishing process or an etching process. As a result, the backside of gate stack 60L and the source/drain regions 50L as shown in FIG. 9D are exposed.

FIG. 9E illustrates the formation of contact plugs 346, which are formed in dielectric layers 348. Bond layer 350 and bond pads 352 are then formed, with bond pads 352 being over and electrically connected to contact plugs 346.

FIGS. 9F through 9I illustrate the formation of upper wafer 102 and the formation and the connection of transistor 10U in accordance with some embodiments. The processes are essentially the same as the formation of the lower wafer 2 as shown in FIGS. 9A through 9G. Accordingly, the formation processes are illustrated, but are not discussed in detail.

Referring to FIG. 9F, a transistor 10U is formed in wafer 102, and includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L.

Further referring to FIG. 9F, after the formation of transistor 10U, contact plugs 138U and vias 335′ are formed to connect to source/drain regions 50U. A front-side interconnect structure includes a plurality of metal layers (with metal line 336′ illustrated as an example) is formed on the front side of transistor 10U. Bond layer 338′ is formed over the front-side interconnect structure. Bond layer 338′ is formed as a top layer, and has a planar top surface.

Next, as shown in FIG. 9G, carrier 344′ is attached to the front side of upper wafer 102. Carrier 344′ may include substrate 342′ and bond layer 340′, which may be selected from essentially the same groups of candidate materials for forming substrate 342 and bond layer 340 as shown in FIG. 9C. The structure shown in FIG. 9G is then flipped upside down, and the resulting structure is shown in FIG. 9H.

FIG. 9I illustrates the formation of contact plugs 346′, which are formed in dielectric layers 348′. Bond layer 350′ and bond pads 352′ are then formed, with bond pads 352′ being over and electrically connected to contact plugs 346′.

Referring to FIG. 9J, wafer 2 is bonded to wafer 102. The bonding process may include hybrid bonding, which includes the bonding of bond pads 352 and 352′ through metal-to-metal direct bonding, and the bonding of bond layers 350 and 350′ through fusion bonding. Accordingly, source/drain regions 50L and source/drain regions 50U are interconnected through contact plugs 346 and 346′ and bond pads 352 and 352′. Furthermore, metal lines 336 and 336′ are interconnected through contact plugs 346 and 346′ and bond pads 352 and 352′.

In subsequent processes, either one or both of carriers 344 and 344′ may be removed. More layers/features may be formed, and the resulting composite wafer 104 may be sawed into dies. In the resulting dies obtained from the singulated composite wafer 104, the bonded bond pads 352 and 35′ act as parts of the local interconnect for interconnecting source/drain regions 50L and 50U.

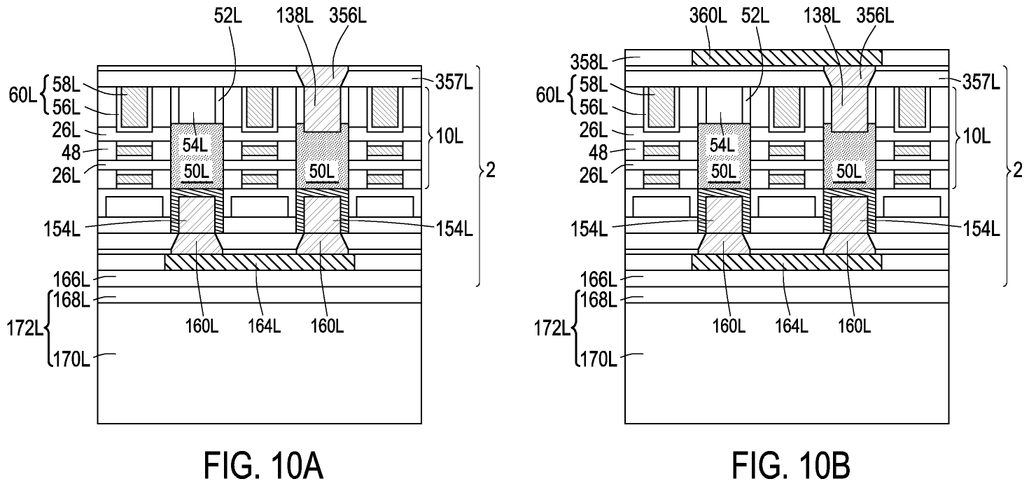

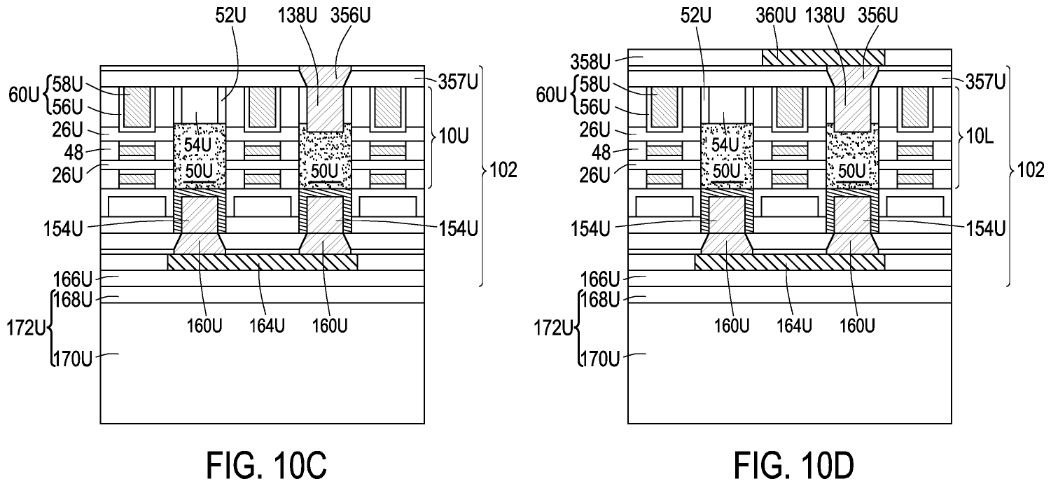

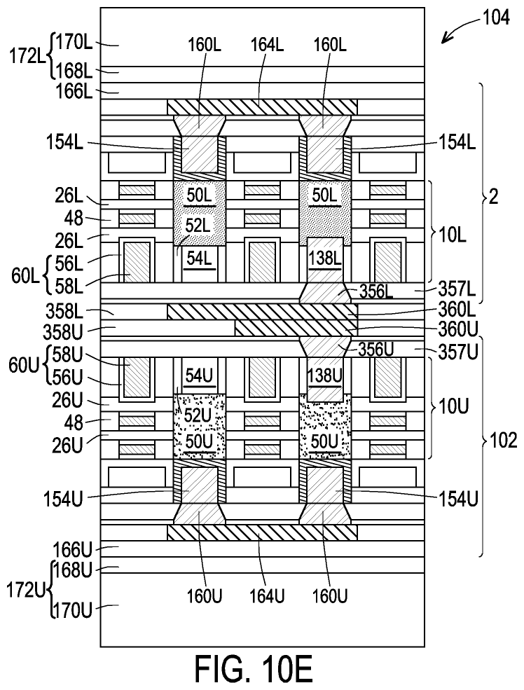

FIGS. 10A-10E illustrate the cross-sectional views of intermediate stages in the formation of CFETs and local interconnects in accordance with alternative embodiments of the present disclosure. The corresponding bonding process is also referred to as a face-to-face process since the front side of the bottom transistors (and the bottom die/wafer) is bonded to the front side of the upper transistors (and the upper die/wafer). Since the front sides of the lower wafer and the upper wafer are bonded to each other, the interconnect structures in the lower wafer and the upper wafer will be formed on the backsides of the respective wafers.

The processes and the resulting structures are essentially the same as what are shown in FIGS. 7 through 7J, except that the bonding of wafers 2 and 102 are through metal lines and pads in metal layers, rather than through small bond pads. Furthermore, on the front side of each of wafers 2 and 102, there may be an additional redistribution structure in addition to the redistribution structure on the backside of the respective transistors.

FIGS. 10A and 10B illustrates the formation of lower wafer 2. The processes of these embodiments are essentially the same as the processes as shown in FIGS. 7A-7H. The resulting structure is shown in FIG. 10A, which includes transistor 10L. In accordance with some embodiments, transistor 10L includes semiconductor nanostructures 26L forming the channels, source/drain regions 50L, and gate stacks 60L wrapping around the semiconductor nanostructures 26L.

Furthermore, contact plugs 154L are formed underlying, and electrically connected to source/drain region 50L. Although not illustrated, a metal silicide layer may be formed between each of the source/drain region 50L and the respective underlying contact plug 154L. A first (backside) interconnect structure including vias 160L and metal lines 164L are formed underlying transistor 10L. The first interconnect structure may include a plurality of metal layers, although one metal layer is illustrated.

On top of source/drain regions 50L, contact plugs 138L are formed overlying, and electrically connecting to, source/drain region 50L. Although not illustrated, a metal silicide layer may be formed between each of the source/drain region 50L and the respective overlying contact plug 138L. A second (front-side) interconnect structure including vias 356L and metal lines 360L (FIG. 10B) is formed overlying, and electrically connected to, transistor 10L. The vias 356L are in dielectric layer 357L, and metal lines 360L are in dielectric layer 358L. Dielectric layers 357L and 358L may be formed of low-k dielectric materials, PSG, BSG, PBSG, undoped silicate glass, silicon oxide, silicon nitride, or the like. In accordance with some embodiments, the front-side interconnect structure includes a single metal layer, which is the metal layer comprising metal line 360L. In accordance with alternative embodiments, there may be a plurality of metal layers for redistributing signals, voltages, and/or currents, and metal line 360L is in the topmost metal layer of the front-side interconnect structure.

Metal line 360L may include a first portion overlapping a first source/drain regions 50L and a second portion directly over a second source/drain regions 50L. Accordingly, while not illustrated in the illustrated plane, metal line 360L may be used for landing deep contact plugs (which may penetrate a lower transistor or an upper transistor) that are connected to other transistors.

FIGS. 10C and 10D illustrate the formation of upper wafer 102. The processes of these embodiments are also essentially the same as the processes as shown in FIGS. 7A-7H. The resulting structure is shown in FIG. 10C, which includes transistor 10U. In accordance with some embodiments, transistor 10U includes semiconductor nanostructures 26U forming the channels, source/drain regions 50U, and gate stacks 60U wrapping around the semiconductor nanostructures 26U.

Furthermore, contact plugs 154U are formed underlying, and electrically connected to source/drain region 50U. Although not illustrated, a metal silicide layer may be formed between each of the source/drain region 50U and the respective underlying contact plug 154U. A first interconnect structure including vias 160U and metal lines 164U is formed underlying transistor 10U. The first interconnect structure may include a plurality of metal layers, although one metal layer is illustrated.

On top of source/drain regions 50U, contact plugs 138U are formed underlying, and electrically connected to source/drain region 50U. Although not illustrated, a metal silicide layer may be formed between each of the source/drain region 50U and the respective overlying contact plug 138U.

Referring to FIG. 10D, a second interconnect structure including vias 356U and metal lines 360U is formed overlying, and electrically connected to, transistor 10U. The vias 356U are in dielectric layer 357U, and metal lines 360U are in dielectric layer 358U. Dielectric layers 357U and 358U may be formed of low-k dielectric materials, PSG, BSG, PBSG, undoped silicate glass, silicon oxide, silicon nitride, or the like. In accordance with some embodiments, the second interconnect structure includes a single metal layer, which is the metal layer comprising metal line 360U. In accordance with alternative embodiments, there may be a plurality of metal layers for redistributing signals and electrical connections, and metal lines 360U are in the topmost metal layers of the interconnect structure.

Referring to FIG. 10E, wafer 2 is bonded to wafer 102. The bonding process may include hybrid bonding, which includes the bonding of bond pad portions of metal lines 360U and 360L through metal-to-metal direct bonding, and the bonding of bond layers 358U and 358L through fusion bonding. Metal lines 360U and 360L are also alternatively referred to as bond pads throughout the description. Accordingly, source/drain regions 50L and source/drain regions 50U are interconnected through contact plugs 138U and 138L, vias 356U and 356L, and metal lines 360U and 360L. Furthermore, metal lines 164L and 164U are interconnected through the illustrated vias and contact plugs.

In subsequent processes, either one or both of carriers 172L and 172U may be removed. More layers/features may be formed, and the resulting composite wafer 104 may be sawed into dies. In the resulting dies obtained from the singulated composite wafer 104, the bonded large bond pads 360L and 360U act as parts of the local interconnect for interconnecting source/drain regions 50L and 50U.

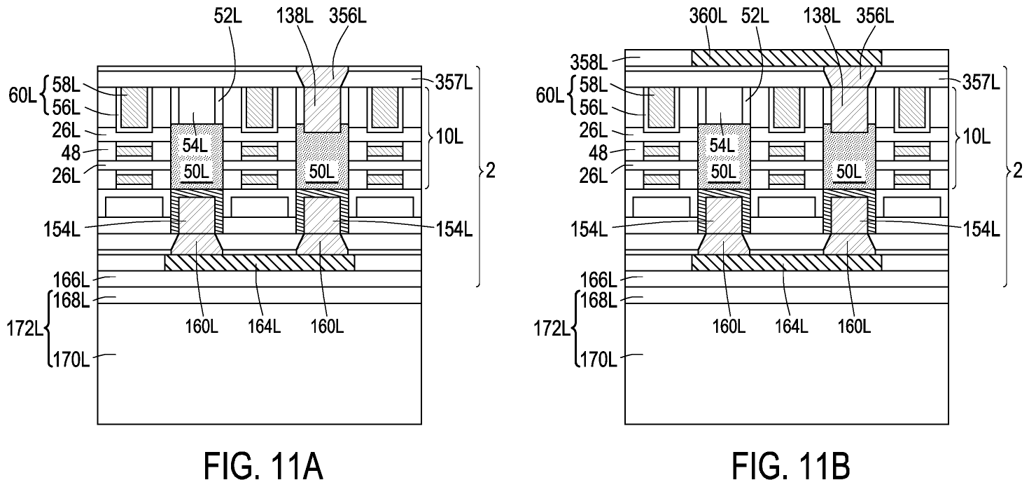

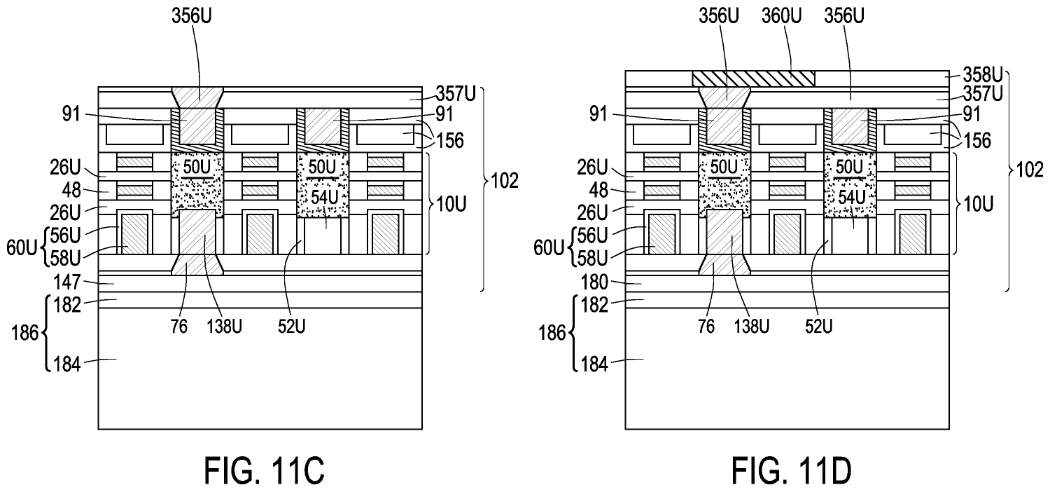

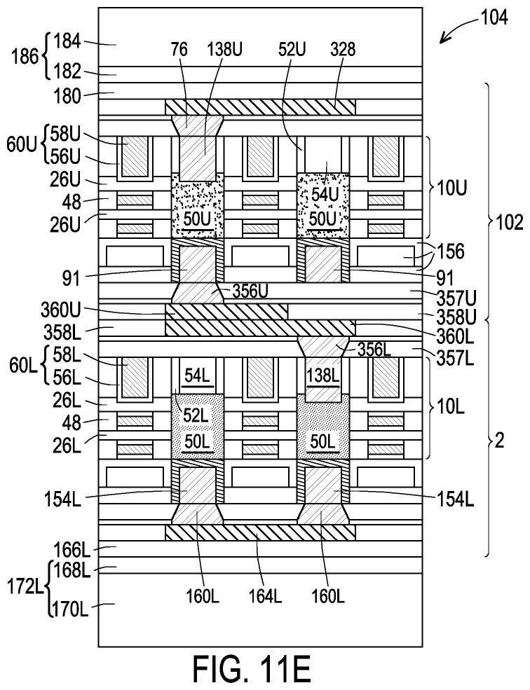

FIGS. 11A-11E illustrate the cross-sectional views of intermediate stages in the formation of CFETs and local interconnects in accordance with alternative embodiments of the present disclosure. The corresponding bonding process is also referred to as a face-to-back process since the front side of the bottom transistors (and the bottom die/wafer) is bonded to the backside of the upper transistors (and the upper die/wafer). Since the front side of the lower wafer is bonded to the backside the upper wafer, the interconnect structures in the lower wafer and the upper wafer are formed on the backside and the front side, respectively, of the lower wafer and the upper wafer.

The processes and the resulting structures are essentially the same as what are shown in FIGS. 8A through 8G, except that the bonding of wafers 2 and 102 are through metal lines and pads in metal layers, rather than through small bond pads. Furthermore, on the bonded side of each of wafers 2 and 102, there may be an additional redistribution structure in addition to the redistribution structure on their opposite sides.

FIGS. 11A and 11B illustrate the formation of lower wafer 2. The corresponding processes and structures are also essentially the same as that shown in FIGS. 10A and 10B, respectively. In accordance with some embodiments, transistor 10L includes semiconductor nanostructures 26L forming the channels, source/drain regions 50L, and gate stacks 60L wrapping around the semiconductor nanostructures 26L.

Furthermore, contact plugs 154L are formed underlying, and electrically connected to source/drain region 50L. Although not illustrated, a metal silicide layer may be formed between each of the source/drain region 50L and the respective underlying contact plug 154L. A first interconnect structure including vias 160L and metal lines 164L are formed underlying transistor 10L. The first interconnect structure may include a plurality of metal layers, although one metal layer is illustrated.

On top of source/drain regions 50L, contact plugs 138L are formed overlying, and electrically connected to source/drain region 50L. Although not illustrated, a metal silicide layer may be formed between each of the source/drain region 50L and the respective overlying contact plug 138L.

Referring to FIG. 11B, a second interconnect structure including vias 356L and metal lines 360L is formed overlying, and electrically connected to, transistor 10L. The vias 356L are in dielectric layer 357L, and metal lines 360L are in dielectric layer 358L. Dielectric layers 357L and 358L may be formed of low-k dielectric materials, PSG, BSG, PBSG, undoped silicate glass, silicon oxide, silicon nitride, or the like. In accordance with some embodiments, the second interconnect structure includes a single metal layer, which is the metal layer comprising metal line 360L. In accordance with alternative embodiments, there may be a plurality of metal layers for redistributing signals and electrical connections, and meta lines 360L are in the topmost metal layer of the second interconnect structure.

FIGS. 11C and 11D illustrate the formation of upper wafer 102. The processes of these embodiments are also essentially the same as the processes as shown in FIGS. 8B-8F. The resulting structure is shown in FIG. 11C, which includes transistor 10U. In accordance with some embodiments, transistor 10U includes semiconductor nanostructures 26U forming the channels, source/drain regions 50U, and gate stacks 60U wrapping around the semiconductor nanostructures 26U.

Furthermore, contact plugs 138U are formed underlying, and electrically connected to source/drain region 50U. Although not illustrated, a metal silicide layer may be formed between each of the source/drain region 50U and the respective underlying contact plug 138U. A first interconnect structure including vias 76 and metal lines 328 are formed underlying transistor 10U. The first interconnect structure may include a plurality of metal layers, although one metal layer is illustrated.

On top of source/drain regions 50U, contact plugs 91 are formed overlying, and electrically connected to source/drain region 50U. Although not illustrated, a metal silicide layer may be formed between each of the source/drain region 50U and the respective overlying contact plug 91. A second interconnect structure including vias 356U and metal lines 360U are formed overlying, and electrically connected to, transistor 10U. The vias 356U are in dielectric layer 357U, and metal lines 360U are in dielectric layer 358U. Dielectric layers 357U and 358U may be formed of low-k dielectric materials, PSG, BSG, PBSG, undoped silicate glass, silicon oxide, silicon nitride, or the like. In accordance with some embodiments, the second interconnect structure includes a single metal layer, which is the metal layer comprising metal line 360U. In accordance with alternative embodiments, there may be a plurality of metal layers for redistributing signals and electrical connections, and meta lines 360U are in the topmost metal layer of the second interconnect structure.

Metal line 360U may include a first portion overlapping a first source/drain regions 50U and a second portion vertically offset from the first source/drain regions 50U. Accordingly, metal line 360U is larger than the respective underly source/drain region 50U in order to reduce the contact resistance between metal lines 360L and 360U, which are bonded to each other in the subsequent process.

Referring to FIG. 11E, wafer 2 is bonded to wafer 102. The bonding process may include hybrid bonding, which includes the bonding of the bond pad portions of metal lines 360U and 360L through metal-to-metal direct bonding, and the bonding of bond layers 358U and 358L through fusion bonding. Accordingly, source/drain regions 50L and source/drain regions 50U are interconnected through the contact plugs and vias in between. Furthermore, metal lines 164L and 164U are interconnected through the contact plugs and vias in between.

In subsequent processes, either one or more of the carriers 172L and 186 may be removed. More layers/features may be formed, and the resulting composite wafer 104 may be sawed into dies. In the resulting dies obtained from the singulated composite wafer 104, the bonded large bond pads (parts of metal lines 360U and 360L) act as parts of the local interconnect for interconnecting source/drain regions 50L and 50U.

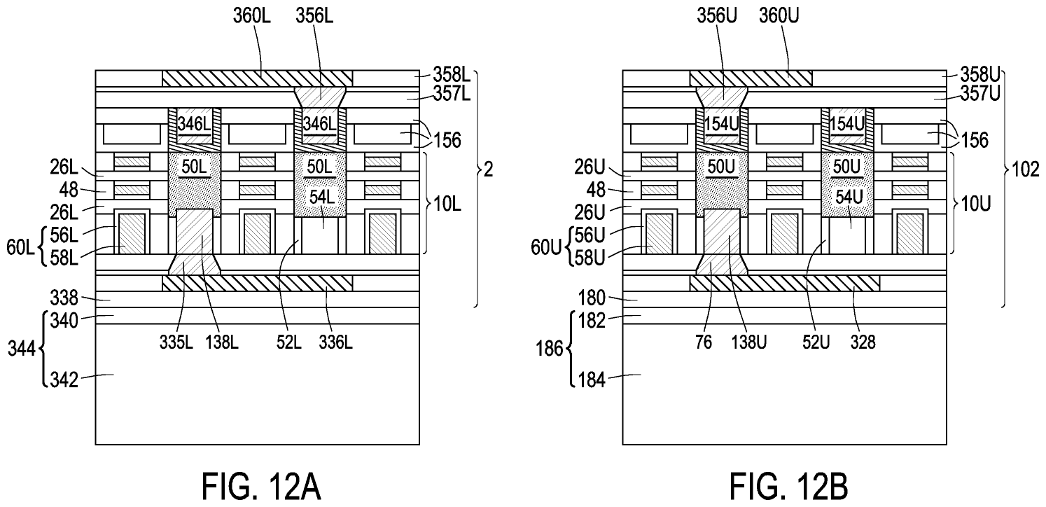

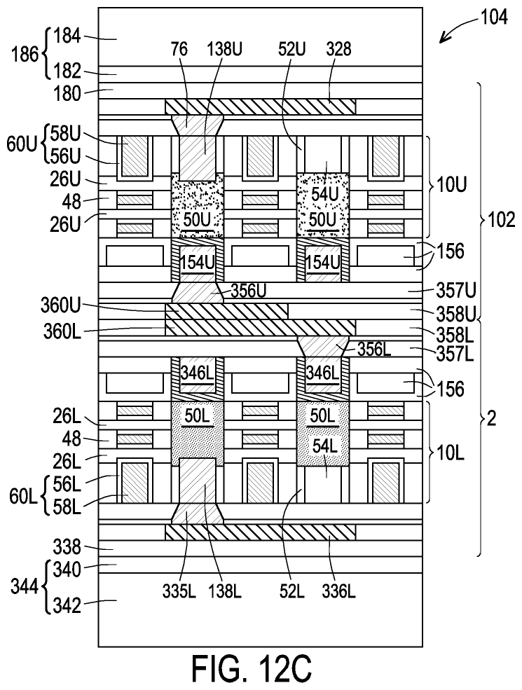

FIGS. 12A-12C illustrate the cross-sectional views of intermediate stages in the formation of CFETs and local interconnects in accordance with alternative embodiments of the present disclosure. The corresponding bonding process is also referred to as a back-to-back process since the backside of the bottom transistors (and the bottom die/wafer) is bonded to the backside of the upper transistors (and the upper die/wafer). Since the backsides of the lower wafer and the upper wafer are bonded to each other, the interconnect structures in the lower wafer and the upper wafer will be formed on the front sides of the respective wafers.

The processes and the resulting structures are essentially the same as what are shown in FIGS. 9A through 9J, except that the bonding of wafers 2 and 102 are through metal lines and pads in metal layers, rather than through small bond pads. Furthermore, on the bonded sides of each of wafers 2 and 102, there may be an additional redistribution structure in addition to the redistribution structure on the backside of the respective transistors.

FIG. 12A illustrates the formation of lower wafer 2 in accordance with some embodiments. Transistors 10L are formed in lower wafer 2. In accordance with some embodiments, transistor 10L includes semiconductor nanostructures 26L forming the channels, source/drain regions 50L, and gate stacks 60L wrapping around the semiconductor nanostructures 26L. An additional interconnect structure including dielectric layers 357L and 358L, via 356L, and metal line 360L is also formed. The formation process for forming the structure that is below the first interconnect structure may be essentially the same as the process shown in FIGS. 9A and 9B, and the details are not repeated herein. The first interconnect structure includes vias 335L and metal lines 336L, which are underlying and electrically connected to contact plugs 138L.

On top of source/drain regions 50L, contact plugs 346L are formed over, and electrically connected to source/drain region 50L. Although not illustrated, a metal silicide layer may be formed between each of the source/drain region 50L and the respective overlying contact plug 346L.

A second interconnect structure including vias 356L and metal lines 360L is formed overlying, and electrically connected to, transistor 10L. The vias 356L are in dielectric layer 357L, and metal lines 360L are in dielectric layer 358L. Dielectric layers 357L and 358L may be formed of low-k dielectric materials, PSG, BSG, PBSG, undoped silicate glass, silicon oxide, silicon nitride, or the like.

In accordance with some embodiments, the second interconnect structure includes a single metal layer, which is the metal layer comprising metal line 360L. In accordance with alternative embodiments, the second interconnect structure may include a plurality of metal layers for redistributing signals and electrical connections, and metal lines 360L are in the topmost metal layer in the second interconnect structure.

FIG. 12B illustrates the formation of upper wafer 102. The processes of these embodiments are also essentially the same as the processes as shown in FIGS. 8B-8F. The resulting structure is shown in FIG. 11C, which includes transistor 10U. In accordance with some embodiments, transistor 10U includes semiconductor nanostructures 26U forming the channels, source/drain regions 50U, and gate stacks 60U wrapping around the semiconductor nanostructures 26U.

Furthermore, contact plugs 138U are formed underlying, and electrically connected to source/drain region 50U. Although not illustrated, a metal silicide layer may be formed between each of the source/drain region 50U and the respective underlying contact plug 138U. A first interconnect structure including vias 76 and metal lines 328 are formed underlying transistor 10U. The first interconnect structure may include a plurality of metal layers, although one metal layer is illustrated.

On top of source/drain regions 50U, contact plugs 154U are formed over, and electrically connected to source/drain region 50U. Although not illustrated, a metal silicide layer may be formed between each of the source/drain region 50U and the respective overlying contact plug 154U. A second interconnect structure including vias 356U and metal lines 360U are formed overlying, and electrically connected to, transistor 10U. The via 356U is in dielectric layer 357U, and metal lines 360U are in dielectric layer 358U. Dielectric layers 357U and 358U may be formed of low-k dielectric materials, PSG, BSG, PBSG, undoped silicate glass, silicon oxide, silicon nitride, or the like.

In accordance with some embodiments, the second interconnect structure includes a single metal layer, which is the metal layer comprising metal line 360U. In accordance with alternative embodiments, there may be a plurality of metal layers for redistributing signals and electrical connections, and metal lines 360U are in the topmost metal layer in the second interconnect structure.

Referring to FIG. 12C, wafer 2 is bonded to wafer 102. The bonding process may include hybrid bonding, which includes the bonding the bond pad portions of metal lines 360U and 360L through metal-to-metal direct bonding, and the bonding of bond layers 358U and 358L through fusion bonding. Accordingly, source/drain regions 50L and source/drain regions 50U are interconnected through the conductive features in between. Furthermore, metal lines 336L and 328 are interconnected through the conductive features in between.

In subsequent processes, either one or both of carriers 344 and 186 may be removed. More layers/features may be formed, and the resulting composite wafer 104 may be sawed into dies. In the resulting dies obtained from the singulated composite wafer 104, the bonded large bond pads (parts of metal lines 360U and 360L) act as parts of the local interconnect for interconnecting source/drain regions 50L and 50U.

The embodiments of the present disclosure have some advantageous features. By adopting parallel formation process or sequential formation process, the design of the upper transistors and lower transistors may have more flexibility such as in selecting different crystal orientations of the channels, different numbers of nanostructures, etc. The upper transistor and the lower transistor may also be different types of transistor such as GAA transistors or FinFETs. Also, inter-metal may be formed between the upper transistors and the lower transistors to provide more routing ability.

In accordance with some embodiments of the present disclosure, a method comprises forming a first transistor in a first wafer, wherein the first transistor comprises a first source/drain region; forming a first bond pad electrically coupling to the first source/drain region; forming an second transistor in a second wafer, wherein the second transistor comprises a second source/drain region; forming a second bond pad electrically coupling to the second source/drain region; and bonding the second wafer to the first wafer, with the second bond pad being bonded to the first bond pad. In an embodiment, the method further comprises forming a first bond layer, with the first bond pad being in the first bond layer; and forming second bond layer, with the second bond pad being in the second bond layer, wherein the first bond layer is bonded to the second bond layer.

In an embodiment, the first bond pad is a part of a metal feature that comprises a first portion vertically aligned to the first source/drain region; and a second portion vertically aligned to the second source/drain region. In an embodiment, the first source/drain region is vertically offset from the second source/drain region. In an embodiment, the first source/drain region is vertically aligned to the second source/drain region. In an embodiment, both of the first bond pad and the second bond pad are vertically aligned to both of the first source/drain region and the second source/drain region. In an embodiment, the first transistor is bonded to the second transistor through back-to-back bonding.

In an embodiment, the first transistor is bonded to the second transistor through face-to-back bonding. In an embodiment, the first transistor is bonded to the second transistor through face-to-face bonding. In an embodiment, the method further comprises forming a first interconnect structure electrically connecting to the first transistor, wherein the first interconnect structure comprises a first plurality of metal layers; and forming a second interconnect structure electrically connecting to the second transistor, wherein the second interconnect structure comprises a second plurality of metal layers, and wherein the first interconnect structure and the second interconnect structure are on opposing sides of a combined structure comprising both of the first transistor and the second transistor.

In accordance with some embodiments of the present disclosure, a method comprises forming a first transistor in a first wafer, wherein the first transistor comprises a first gate stack; and a first source/drain region and a second source/drain region on opposing sides of the first gate stack; forming a second transistor in a second wafer, wherein the first transistor and the second transistor collectively form complementary field-effect transistors (CFETs), and wherein the second transistor comprises a second gate stack; and a third source/drain region and a fourth source/drain region on opposing sides of the second gate stack, wherein the first source/drain region is electrically coupled to the third source/drain region by an electrical path; forming a first interconnect structure on the first wafer and electrically connecting to the first transistor; and forming a second interconnect structure on the second wafer and electrically connecting to the second transistor.

In an embodiment, the method further comprises forming a third interconnect structure comprising a plurality of metal layers, wherein the third interconnect structure is between the first transistor and the second transistor, and wherein the electrical path comprises a portion of the third interconnect structure. In an embodiment, the method further comprises forming a first bond pad in the first wafer and comprising a first portion vertically aligned to the first source/drain region; and a second portion vertically aligned to the second source/drain region; and forming a second bond pad in the second wafer, wherein the first portion is bonded to the second bond pad, and the first bond pad the second bond pad electrically connect the first source/drain region to the third source/drain region.

In an embodiment, the first source/drain region is vertically aligned to the third source/drain region. In an embodiment, the first source/drain region is vertically offset from the third source/drain region. In an embodiment, the method further comprises bonding the first wafer comprising the first transistor to the second wafer comprising the second transistor. In an embodiment, the first transistor and the second transistor are back-to-back. In an embodiment, the first transistor and the second transistor are face-to-back.

In accordance with some embodiments of the present disclosure, a method comprises forming a first wafer comprising forming a first transistor comprising a first gate stack; and a first source/drain region and a second source/drain region on opposing sides of the first gate stack; and forming a first bond pad on a backside of the first transistor, wherein the first bond pad extends to positions vertically aligned to both of the first source/drain region and the second source/drain region, and is electrically connected to one of the first source/drain region and the second source/drain region; forming a second wafer comprising forming a second transistor comprising a second gate stack; and a third source/drain region and a fourth source/drain region on opposing sides of the second gate stack, wherein the third source/drain region and the fourth source/drain region are vertically aligned to the first source/drain region and the second source/drain region, respectively; and forming a second bond pad on a side of the second transistor, wherein the second bond pad extends is vertically aligned to the third source/drain region, and is vertically offset from the fourth source/drain region; and bonding the first wafer to the second wafer, wherein the first bond pad is bonded to the second bond pad. In an embodiment, the second source/drain region is electrically connected to the third source/drain region by the first bond pad and the second bond pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first transistor in a first wafer, wherein the first transistor comprises a first source/drain region;
forming a first bond pad electrically coupling to the first source/drain region;
forming an second transistor in a second wafer, wherein the second transistor comprises a second source/drain region;
forming a second bond pad electrically coupling to the second source/drain region; and
bonding the second wafer to the first wafer, with the second bond pad being bonded to the first bond pad.

2. The method of claim 1 further comprising:
forming a first bond layer, with the first bond pad being in the first bond layer; and
forming second bond layer, with the second bond pad being in the second bond layer, wherein the first bond layer is bonded to the second bond layer.

3. The method of claim 1, wherein the first bond pad is a part of a metal feature that comprises:
a first portion vertically aligned to the first source/drain region; and
a second portion vertically aligned to the second source/drain region.

4. The method of claim 1, wherein the first source/drain region is vertically offset from the second source/drain region.

5. The method of claim 1, wherein the first source/drain region is vertically aligned to the second source/drain region.

6. The method of claim 1, wherein both of the first bond pad and the second bond pad are vertically aligned to both of the first source/drain region and the second source/drain region.

7. The method of claim 1, wherein the first transistor is bonded to the second transistor through back-to-back bonding.

8. The method of claim 1, wherein the first transistor is bonded to the second transistor through face-to-back bonding.

9. The method of claim 1, wherein the first transistor is bonded to the second transistor through face-to-face bonding.

10. The method of claim 1 further comprising:
forming a first interconnect structure electrically connecting to the first transistor, wherein the first interconnect structure comprises a first plurality of metal layers; and
forming a second interconnect structure electrically connecting to the second transistor, wherein the second interconnect structure comprises a second plurality of metal layers, and wherein the first interconnect structure and the second interconnect structure are on opposing sides of a combined structure comprising both of the first transistor and the second transistor.

11. A method comprising:
forming a first transistor in a first wafer, wherein the first transistor comprises:
a first gate stack; and
a first source/drain region and a second source/drain region on opposing sides of the first gate stack;
forming a second transistor in a second wafer, wherein the first transistor and the second transistor collectively form complementary field-effect transistors (CFETs), and wherein the second transistor comprises:
a second gate stack; and
a third source/drain region and a fourth source/drain region on opposing sides of the second gate stack, wherein the first source/drain region is electrically coupled to the third source/drain region by an electrical path;
forming a first interconnect structure on the first wafer and electrically connecting to the first transistor; and
forming a second interconnect structure on the second wafer and electrically connecting to the second transistor.

12. The method of claim 11 further comprising forming a third interconnect structure comprising a plurality of metal layers, wherein the third interconnect structure is between the first transistor and the second transistor, and wherein the electrical path comprises a portion of the third interconnect structure.

13. The method of claim 11 further comprising:
forming a first bond pad in the first wafer and comprising:
a first portion vertically aligned to the first source/drain region; and
a second portion vertically aligned to the second source/drain region; and
forming a second bond pad in the second wafer, wherein the first portion is bonded to the second bond pad, and the first bond pad the second bond pad electrically connect the first source/drain region to the third source/drain region.

14. The method of claim 11, wherein the first source/drain region is vertically aligned to the third source/drain region.

15. The method of claim 11, wherein the first source/drain region is vertically offset from the third source/drain region.

16. The method of claim 11 further comprising bonding the first wafer comprising the first transistor to the second wafer comprising the second transistor.

17. The method of claim 11, wherein the first transistor and the second transistor are back-to-back.

18. The method of claim 11, wherein the first transistor and the second transistor are face-to-back.

19. A method comprising:
forming a first wafer comprising:
forming a first transistor comprising:
a first gate stack; and
a first source/drain region and a second source/drain region on opposing sides of the first gate stack; and
forming a first bond pad on a backside of the first transistor, wherein the first bond pad extends to positions vertically aligned to both of the first source/drain region and the second source/drain region, and is electrically connected to one of the first source/drain region and the second source/drain region;
forming a second wafer comprising:
forming a second transistor comprising:
a second gate stack; and
a third source/drain region and a fourth source/drain region on opposing sides of the second gate stack, wherein the third source/drain region and the fourth source/drain region are vertically aligned to the first source/drain region and the second source/drain region, respectively; and
forming a second bond pad on a side of the second transistor, wherein the second bond pad extends is vertically aligned to the third source/drain region, and is vertically offset from the fourth source/drain region; and
bonding the first wafer to the second wafer, wherein the first bond pad is bonded to the second bond pad.

20. The method of claim 19, wherein the second source/drain region is electrically connected to the third source/drain region by the first bond pad and the second bond pad.
